(19) United States
(12) Patent Application Publication
(10) Pub. No.: US 2026/0282778 A1
(43) Pub. Date: Sep. 17, 2026

(54) METHOD OF MANUFACTURING SEMICONDUCTOR DEVICE INCLUDING THERMAL TREATING A DIELECTRIC FILM

(71) Applicant: Samsung Electronics Co., Ltd., Suwon-si (KR)

(72) Inventors: Gilwoon Lee, Suwon-si (KR); Junghwan Kim, Suwon-si (KR); Junhee Kim, Suwon-si (KR); Hokyun An, Suwon-si (KR); Eunha Lee, Suwon-si (KR); Chunhyung Chung, Suwon-si (KR)

(73) Assignee: Samsung Electronics Co., Ltd., Suwon-si (KR)

(21) Appl. No.: 19/561,052

(22) Filed: Mar. 9, 2026

(30) Foreign Application Priority Data
Mar. 11, 2025 (KR) 10-2025-0031659

(51) Int. Cl. H10P 14/60; H10D 64/01; H10P 95/90

(52) U.S. Cl. CPC H10P 14/6544; H10D 64/01332; H10P 95/90

(57) ABSTRACT

A method of manufacturing a semiconductor device includes forming a gate interface film on a substrate, forming a preliminary dielectric film structure including a metal silicon oxide on the gate interface film, forming a dielectric film structure including a phase-separated first region and a second region by heat-treating the preliminary dielectric film structure at a temperature within a range of about 650° C. to about 850° C. in a nitrogen atmosphere, forming a gate electrode on the preliminary dielectric film structure, and forming a capping insulating film on the gate electrode, wherein the heat-treating includes heat-treating at a first temperature, and heat-treating at a second temperature that is different from the first temperature.

### CROSS-REFERENCE TO RELATED APPLICATIONS

This present application claims priority to and the benefit under 35 U.S.C. § 119(a)-(d) of Korean Patent Application No. 10-2025-0031659, filed on Mar. 11, 2025, in the Korean Intellectual Property Office, the entire disclosure of which is incorporated herein by reference.

### FIELD

The disclosure pertains to a method of manufacturing a semiconductor device and more particularly to a method of manufacturing a semiconductor device including thermal (e.g., heat) treating a dielectric film.

### BACKGROUND

Due to the characteristics of miniaturization, multi-functionality, and/or low manufacturing cost, semiconductor devices are receiving attention as important elements in the electronics industry. As the electronics industry is highly developed, the trend toward high integration of semiconductor devices is intensifying. As semiconductor devices become highly integrated, the leakage current characteristics in transistors have a significant impact on the performance of semiconductor devices.

### SUMMARY

The disclosed concepts provide a semiconductor device capable of reducing or preventing leakage current by forming a dielectric film structure including both a region having a high dielectric constant and a region having a low dielectric constant.

According to aspects of the disclosed concepts, there is provided a method of manufacturing a semiconductor device, the method includes forming a gate interface film on a substrate, forming, on the gate interface film, a preliminary dielectric film structure including a metal silicon oxide, forming a dielectric film structure including a phase-separated first region and a second region by heat-treating the preliminary dielectric film structure at a temperature within a range of about 650° C. to about 850° C. in a nitrogen atmosphere, forming a gate electrode on the preliminary dielectric film structure, and forming a capping insulating film on the gate electrode, wherein the heat-treating of the preliminary dielectric film structure includes heat-treating at a first temperature, and heat-treating at a second temperature that is different from the first temperature.

According to aspects of the disclosed concepts, there is provided a method of manufacturing a semiconductor device, the method includes forming a gate interface film on a substrate, forming a preliminary dielectric film structure including a metal silicon oxide on the gate interface film, forming a dielectric film structure including a phase-separated first region and a second region by heat-treating the preliminary dielectric film structure in a nitrogen atmosphere, forming a gate electrode on the dielectric film structure, and forming a capping insulating film on the gate electrode, wherein the heat-treating of the preliminary dielectric film structure includes heat-treating at a first temperature within a range of about 650° C. to about 750° C.; and heat-treating at a second temperature within a range of about 750 ° C. to about 850° C.

According to aspects of the disclosed concepts, there is provided a method of manufacturing a semiconductor device, the method includes forming a gate interface film on a substrate, forming a preliminary dielectric film structure including a metal silicon oxide on the gate interface film, forming a dielectric film structure including a first region that is phase-separated and a second region by performing a rapid thermal processing (RTP) on the preliminary dielectric film structure at a temperature within a range of about 650° C. to about 850° C., forming a gate electrode on the dielectric film structure, and forming a capping insulating film on the gate electrode, wherein the first region includes a crystallized region and has a dielectric constant within a range from about 18 to about 20, and the second region includes an amorphous region and has a dielectric constant within a range from about 4 to about 5.

According to aspects of the disclosed concepts, there is provided a semiconductor device including a substrate including an active region; a gate interface film on the substrate; a dielectric film structure disposed on the gate interface film, including a metal silicon oxide, and formed by rapid thermal processing (RTP) at a temperature in a range of about 650° C. to about 850° C. in a nitrogen atmosphere, and a gate electrode on the dielectric film structure, wherein the dielectric film structure includes a first region including silicon at a first concentration and a second region including silicon at a second concentration, wherein the first concentration of silicon in the first region is less than the second concentration of silicon in the second region.

In embodiments, the first region may be spaced apart from the gate interface film or the gate electrode with the second region therebetween.

In embodiments, the second region may include a plurality of second regions, and the first region is disposed between the plurality of second regions.

In embodiments, the first region may include a plurality of first regions, and the second region may be disposed between the plurality of first regions.

In embodiments, the first region may include a plurality of first regions, and the plurality of first regions may each be surrounded by the second region.

In embodiments, the first region may include a crystallized region and the second region may include an amorphous region, wherein the first region may include a crystal phase having a high dielectric constant among a plurality of crystal phases of the metal oxide at a higher ratio than a crystal phase having a low dielectric constant among the plurality of crystal phases.

In embodiments, the dielectric constant of the first region may be in a range from about 18 to about 20, and the dielectric constant of the second region may be in a range from about 4 to about 5.

In embodiments, the dielectric film structure may include nitrogen within an amount range of about 2 at % to about 20 at %.

In embodiments, the metal silicon oxide may include at least one of hafnium (Hf), zirconium (Zr), lanthanum (La), and aluminum (Al).

In embodiments, the metal silicon oxide may include hafnium (Hf), the first region may include a crystallized region, the second region may include an amorphous region, and the first region may include a crystal phase having a high dielectric constant among a plurality of crystal phases of hafnium oxide at a higher ratio than a crystal phase having a low dielectric constant among the plurality of crystal phases.

### BRIEF DESCRIPTION OF THE DRAWINGS

Embodiments will be more clearly understood from the following detailed description taken in conjunction with the accompanying drawings in which:

FIG. 1A is a schematic diagram illustrating a semiconductor device according to embodiments;

FIG. 1B is a schematic diagram illustrating a dielectric film structure according to embodiments;

FIGS. 2A to 2D are schematic diagrams illustrating dielectric film structures according to embodiments;

FIG. 3 is a flowchart for explaining a method of manufacturing a semiconductor device, according to embodiments;

FIGS. 4 to 8 are diagrams for explaining a method of manufacturing a semiconductor device, according to embodiments;

FIG. 9 is a schematic diagram illustrating a semiconductor device according to embodiments;

FIG. 10 is a schematic diagram illustrating a semiconductor device according to embodiments;

FIG. 11 is a scanning transmission electron microscopy-high-angle annular dark field (STEM-HAADF) image of a dielectric film structure according to embodiments;

FIG. 12 is a graph showing the results of electron energy loss spectroscopy (EELS) analysis of a transmission electron microscopy an electron microscope (TEM) image of a semiconductor device;

FIG. 13 is a graph comparing the leakage current characteristics of a semiconductor device according to embodiments with a semiconductor device according to a comparative example.

FIGS. 14A and 14B are layout diagrams showing semiconductor devices according to embodiments;

FIG. 15A is a cross-sectional view taken along line A1-A1′ of FIG. 14A;

FIG. 15B is a cross-sectional view taken along line A2-A2′ of FIG. 14A;

FIG. 15C is a cross-sectional view taken along line B-B′ of FIG. 14B;

FIGS. 16A to 28C are cross-sectional views illustrating a process sequence for explaining a method of manufacturing a semiconductor device, according to embodiments of the present invention; and Specifically, FIGS. 16A to 28A are cross-sectional views corresponding to the cross-section along line A1-A1′ of FIG. 14A, FIGS. 16B to 28B are cross-sectional views corresponding to the cross-section along line A2-A2′ of FIG. 14A, and FIGS. 16C to 28C are cross-sectional views corresponding to the cross-section along line B-B′ of FIG. 14B.

### DETAILED DESCRIPTION

Hereafter, the embodiments of the disclosed concepts will be fully described with reference to the accompanying drawings. In the drawings, like reference numerals are used to indicate like elements and the descriptions thereof will not be repeated.

In the specification, the horizontal direction may include a first horizontal direction (X direction) and a second horizontal direction (Y direction) that intersect with each other. A direction intersecting the first horizontal direction (X direction) and the second horizontal direction (Y direction) may be referred to as a vertical direction (Z direction). In the present specification, the vertical level may be referred to as a height level in the vertical direction (Z direction) of any configuration.

In the present specification, as an example, a planar transistor including a channel region and a transistor including nanowires or nanosheets are illustrated, but the application field of the disclosed concepts is not limited thereto.

The disclosed concepts relate to a method of manufacturing a semiconductor device, and more specifically, to a method of manufacturing a semiconductor device including a metal silicon oxide.

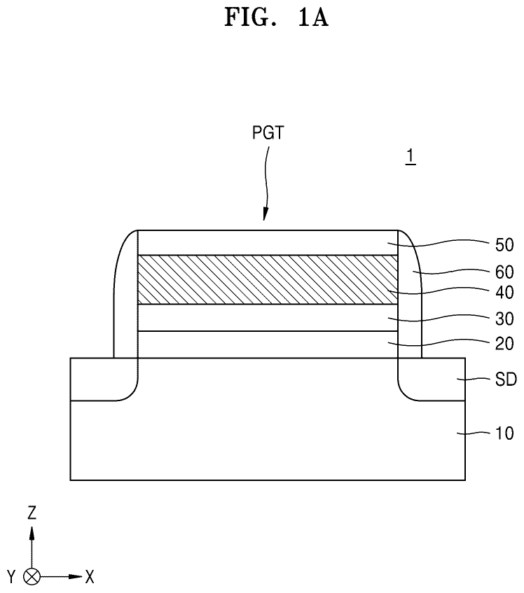

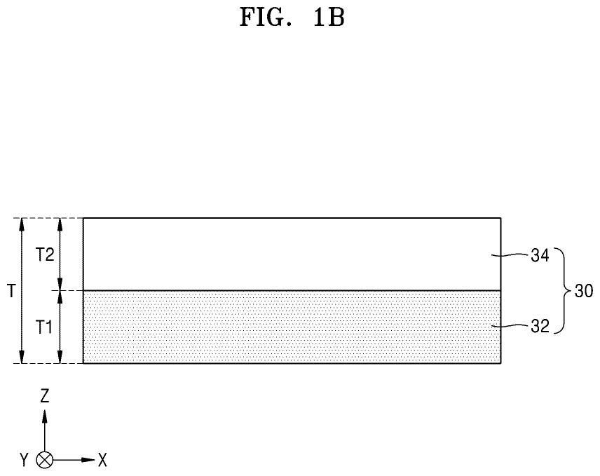

FIG. 1A is a schematic diagram illustrating a semiconductor device 1 according to embodiments. FIG. 1B is a schematic diagram illustrating a dielectric film structure 30 according to embodiments.

Referring to FIGS. 1A and 1B, the semiconductor device 1 includes a substrate 10, a source/drain region SD on the substrate 10, a gate interface film 20 on the substrate 10, a dielectric film structure 30 on the gate interface film 20, a gate electrode 40 on the dielectric film structure 30, and a gate capping pattern 50 on the gate electrode 40, wherein the gate interface film 20, the dielectric film structure 30, the gate electrode 40, and the gate capping pattern 50 may constitute a gate structure PGT. The semiconductor device 1 may include a gate spacer 60 covering a sidewall of the gate structure PGT.

The substrate 10 may include a silicon substrate or a silicon-on-insulator (SOI). Alternatively, the substrate 10 may include silicon germanium, silicon germanium on insulator (SGOI), indium antimonide, lead telluride, indium arsenide, indium phosphide, gallium arsenide, or gallium antimonide, but is not limited thereto.

Alternatively, unlike what is illustrated, the substrate 10 may include a base substrate and a channel film disposed on the base substrate. The channel film may include a material that is different from the base substrate. The channel film may include a material having semiconductor properties. At least a portion of the source/drain region SD may be formed within the channel film. As an example, the channel film may include silicon or germanium, which are elemental semiconductor materials. As another example, the channel film may include a compound semiconductor, for example, a Group IV-IV compound semiconductor or a Group III-V compound semiconductor. The Group IV-IV compound semiconductor may be, for example, a binary compound, a ternary compound, or a compound doped with a Group IV element, including at least two of carbon (C), silicon (Si), germanium (Ge), and tin (Sn). The Group III-V compound semiconductor may be, for example, a binary compound, a ternary compound, or a quaternary compound formed by combining at least one of aluminum (Al), gallium (Ga), and indium (In), which are Group III elements, with one of phosphorus (P), arsenic (As), and antimony (Sb), which are Group V elements.

As another example, the channel film may include a two-dimensional (2D) material. The 2D material may include a 2D l allotrope or a 2D compound, and may include at least one of, but is not limited to, graphene, molybdenum disulfide (MoS₂), molybdenum diselenide (MoSe₂), tungsten diselenide (WSe₂), and tungsten disulfide (WS₂).

As another example, the channel film may include an amorphous metal oxide, a polycrystalline metal oxide, or any combination of an amorphous metal oxide and a polycrystalline metal oxide. The metal oxides include one of, for example, indium oxide, tin oxide, zinc oxide, In—Zn oxide (IZO), Sn—Zn oxide, Ba—Sn oxide, Al—Zn oxide, Zn—Mg oxide, Sn—Mg oxide, In—Mg oxide, In—Ga oxide (IGO), In—Ga—Zn oxide (IGZO), In—Al—Zn oxide, In—Sn—Zn oxide (ITZO), In—W—Zn oxide (IWZO), Sn—Ga—Zn oxide, Al—Ga—Zn oxide, Sn—Al—Zn oxide, In—Hf—Zn oxide, In—La—Zn oxide, In—Ce—Zn oxide, In—Pr—Zn oxide, In—Nd—Zn oxide, In—Sm—Zn oxide, In—Eu—Zn oxide, In—Gd—Zn oxide, In—Tb—Zn oxide, In—Dy—Zn oxide, In—Ho—Zn oxide, In—Er—Zn oxide, In—Tm—Zn oxide, In—Yb—Zn oxide, In—Lu—Zn oxide, In—Sn—Ga—Zn oxide, In—Hf—Ga—Zn oxide, In—Al—GaZn oxide, In—Sn—Al—Zn oxide, In—Sn—Hf—Zn oxide, and In—Hf—Al—Zn oxide, but are not limited thereto.

The gate interface film 20 may be disposed on the substrate 10. For example, the gate interface film 20 may include silicon oxide, silicon nitride, silicon oxynitride, oxide/nitride/oxide (ONO), or any combination thereof. However, if the substrate 10 includes a channel film as described above, the gate interface film 20 may include a material that is different from the material described as an example depending on the type of the channel film.

The dielectric film structure 30 may be disposed on the gate interface film 20 and may be spaced apart from an upper surface of the substrate 10 with the gate interface film 20 therebetween. As illustrated in FIG. 1B, the dielectric film structure 30 may include a first region 32 and a second region 34. In FIG. 1B, the second region 34 is shown as being stacked on the first region 32, but the first region 32 may also be stacked on the second region 34.

In embodiments, the first region 32 may be spaced from the gate interface film 20 or the gate electrode 40 with the second region 34 therebetween. In embodiments, the second region 34 may be between the first region 32 and the gate interface film 20. In another embodiment, the second region 34 may be between the first region 32 and the gate electrode 40.

The dielectric film structure 30 may include a metal silicon oxide. For example, the metal silicon oxide may include at least one of hafnium (Hf), zirconium (Zr), lanthanum (La), and aluminum (Al). In embodiments, the dielectric film structure 30 may include a material based on hafnium silicon oxide. The material based on hafnium silicon oxide may have a chemical formula that conforms to stoichiometry or may have a chemical formula that does not conform to stoichiometry. Here, the material based on hafnium silicon oxide may include not only hafnium silicon oxide but also a material including a dopant in hafnium silicon oxide. In embodiments, the dopant may include at least one of, for example, gadolinium (Gd), zirconium (Zr), aluminum (Al), and yttrium (Y).

The first region 32 and the second region 34 are, respectively, a phase separated crystallized region and an amorphous region of metal silicon oxide, which are formed by heat-treating a preliminary dielectric film structure including a metal oxide and a silicon oxide during a process of manufacturing a semiconductor device of the disclosed concepts. The first region 32 may be a crystallized region, and the second region 34 may be an amorphous region.

The first region 32 may include silicon (Si) at a first concentration, the second region 34 may include Si at a second concentration, and the first concentration of the first region 32 may be less than the second concentration of the second region 34. In other words, the metal concentration of the first region 32 may be greater than the metal concentration of the second region 34. For example, the first region 32 and the second region 34 include hafnium (Hf), and the concentration of hafnium (Hf) of the first region 32 may be greater than the concentration of Hf of the second region 34.

The first region 32 may include a crystal phase having a high dielectric constant among the plurality of crystal phases of the metal oxide at a higher ratio than a crystal phase having a low dielectric constant among the plurality of crystal phases. For example, the first region 32 may include Hf, and may include a crystal phase having a high dielectric constant among the plurality of crystal phases of the hafnium oxide at a higher ratio than a crystal phase having a low dielectric constant among the plurality of crystal phases. For example, the first region 32 may include a monoclinic phase (m-HfO₂), a tetragonal phase (t-HfO₂), a cubic phase (c-HfO₂), and an orthorhombic phase (o-HfO₂) of hafnium oxide, and may include a high ratio of the orthorhombic phase having ferroelectric properties and a high permittivity compared to the monoclinic phase, tetragonal phase, and cubic phase having relatively low permittivity. For example, the first region 32 may include an orthorhombic phase of hafnium oxide within a range from about 60% to about 80%, and a monoclinic phase within a range from about 3% to about 10%.

The dielectric constant of the first region 32 may be greater than the dielectric constant of the second region 34. For example, the dielectric constant of the first region 32 may be within a range from about 18 to about 20, and the dielectric constant of the second region 34 may be within a range from about 4 to about 5.

The dielectric film structure 30 is a structure formed by heat-treating a preliminary dielectric film structure including a metal oxide and a silicon oxide in a nitrogen atmosphere. Accordingly, the dielectric film structure 30 may include nitrogen. For example, the dielectric film structure 30 may include nitrogen within a range from about 2 at % to about 20 at %.

The first region 32 of the dielectric film structure 30 may have a first thickness T1 in a direction perpendicular to the upper surface of the substrate 10 (Z direction), and the second region 34 may have a second thickness T2 in a direction perpendicular to the upper surface of the substrate 10 (Z direction). The first thickness T1 of the first region 32 may be the same as or different from the second thickness T2 of the second region 34. In other words, a ratio of the first region 32 to the dielectric film structure 30 may be the same as a ratio of the second region 34, or may be greater or less than the ratio of the second region 34.

The gate electrode 40 may be arranged on the dielectric film structure 30. In embodiments, the gate electrode 40 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and any combination thereof.

The gate capping pattern 50 may be arranged on the gate electrode 40. The gate capping pattern 50 may be configured of a single layer or multiple layers, and may include, for example, at least one of silicon nitride (SiN), silicon oxynitride (SiON), silicon oxide (SiO₂), silicon carbon nitride (SiCN), silicon oxycarbon nitride (SiOCN), and any combination thereof.

The gate spacer 60 may be arranged on sidewalls of the gate interface film 20, the dielectric film structure 30, the gate electrode 40, and the gate capping pattern 50. The gate spacer 60 may be configured of a single layer or multiple layers, and may include an oxide film, a nitride film, or any combination thereof. The gate spacer 60 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and any combination thereof.

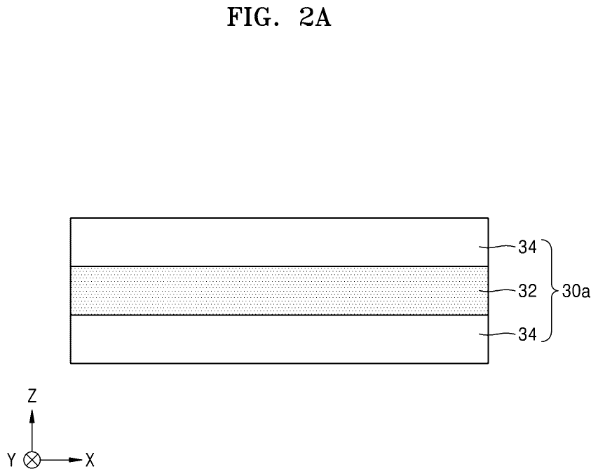

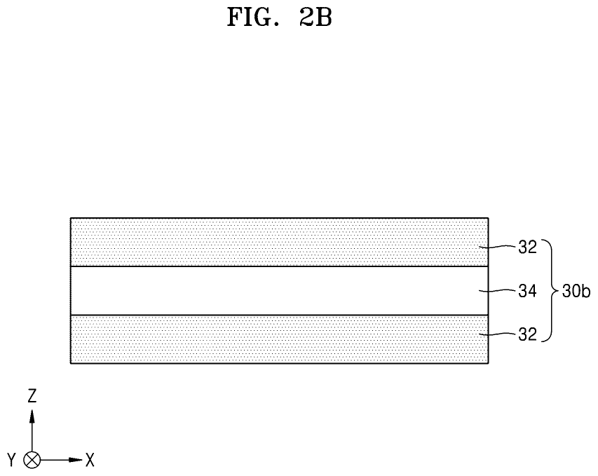

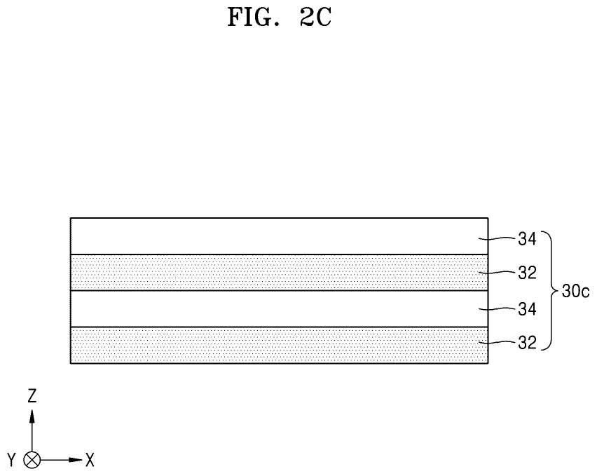

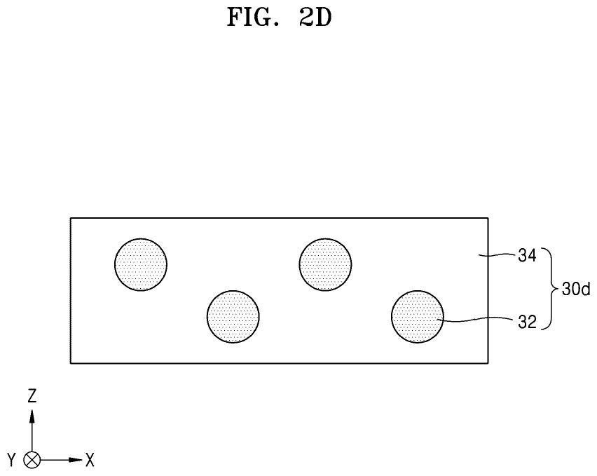

FIGS. 2A to 2D are schematic diagrams illustrating dielectric film structures according to embodiments. Dielectric film structures 30a, 30b, 30c, and 30d illustrated in FIGS. 2A to 2D are configured in a substantially similar manner to the dielectric film structure 30 of FIGS. 1A and 1B, respectively, and thus, the differences will be mainly described below.

Referring to FIG. 2A, the dielectric film structure 30a may include a first region 32 and a plurality of second regions 34. The plurality of second regions 34 may include two second regions 34, as illustrated in FIG. 2A. The first region 32 may be disposed between the plurality of second regions 34. The first region 32 may be spaced apart from the gate interface film 20 with one of the plurality of second regions 34 therebetween, and may be spaced apart from the gate electrode 40 with another of the plurality of second regions 34 therebetween.

Referring to FIG. 2B, the dielectric film structure 30b may include a plurality of first regions 32 and a second region 34. The plurality of first regions 32 may include two first regions 32, as shown in FIG. 2B. The second region 34 may be disposed between the plurality of first regions 32. One of the plurality of first regions 32 may be in contact with the gate interface film 20, and the other may be in contact with the gate electrode 40. Among the plurality of first regions 32, the region that is in contact with the gate interface film 20 may be spaced apart from the gate electrode 40 with the second region 34 therebetween, and among the plurality of first regions 32, the region that is in contact with the gate electrode 40 may be spaced apart from the gate interface film 20 with the second region 34 therebetween.

Referring to FIG. 2C, the dielectric film structure 30c may include a plurality of first regions 32 and a plurality of second regions 34. The plurality of first regions 32 and the plurality of second regions 34 may be alternately stacked on the gate interface film 20. For example, the first region 32 may be arranged on the gate interface film 20, the second region 34 may be arranged on the first region 32, and the first region 32 may be arranged on the second region 34. As another example, the second region 34 may be arranged on the gate interface film 20, the first region 32 may be arranged on the second region 34, and the second region 34 may be arranged on the first region 32.

The plurality of first regions 32 may include two first regions 32, as illustrated in FIG. 2C, but is not limited thereto, and may include three or more first regions 32. The plurality of second regions 34 may include two second regions 34, as shown in FIG. 2C, but is not limited thereto, and may include three or more second regions 34. At least one of the plurality of first regions 32 may be spaced apart from the gate interface film 20 with the at least one of the plurality of second regions 34 therebetween, and at least one of the plurality of first regions 32 may be spaced apart from the gate electrode 40 with the at least one of the plurality of second regions 34 therebetween.

Referring to FIG. 2D, the dielectric film structure 30d may include a plurality of first regions 32 and the second region 34 surrounding the plurality of first regions 32. The plurality of first regions 32 may have a circular shape, as shown in FIG. 2D, but is not limited thereto and may have various shapes. The plurality of first regions 32 may be spaced apart from each other by having a portion of the second region 34 therebetween. The plurality of first regions 32 may include four first regions 32, as shown in FIG. 2D, but is not limited thereto, and may include one, two, three, five or more first regions 32. The second region 34 may surround the plurality of first regions 32 and may be in contact with the gate interface film 20 and/or the gate electrode 40. The plurality of first regions 32 may be spaced apart from the gate interface film 20 and/or the gate electrode 40 with a portion of the second region 34 therebetween.

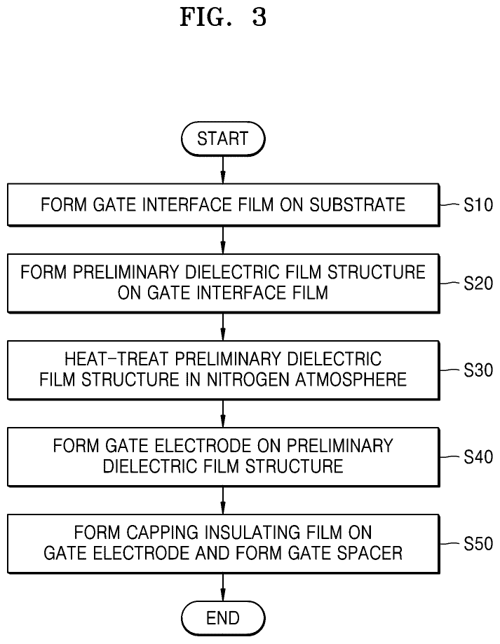

FIG. 3 is a flowchart illustrating a method of manufacturing a semiconductor device, according to embodiments.

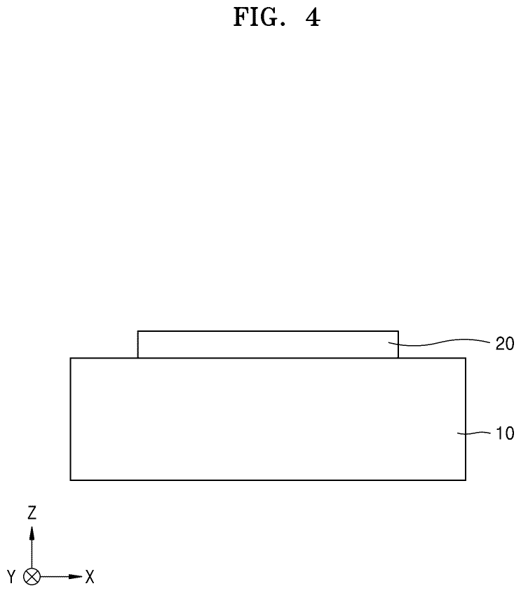

FIGS. 4 to 8 are diagrams illustrating a method of manufacturing a semiconductor device, according to embodiments.

Referring to FIGS. 3 and 4, first, a substrate 10 may be provided. The substrate 10 may include a silicon substrate or a silicon-on-insulator (SOI). Alternatively, the substrate 10 may include, but is not limited to, silicon germanium, silicon germanium on insulator (SGOI), indium antimonide, lead tellurium compound, indium arsenide, indium phosphide, gallium arsenide or gallium antimonide.

After performing a pre-clean on the entire surface of the substrate 10, a gate interface film 20 may be formed on the substrate 10. The gate interface film 20 may include silicon oxide, silicon nitride, silicon oxynitride, oxide/nitride/oxide (ONO), or any combination thereof.

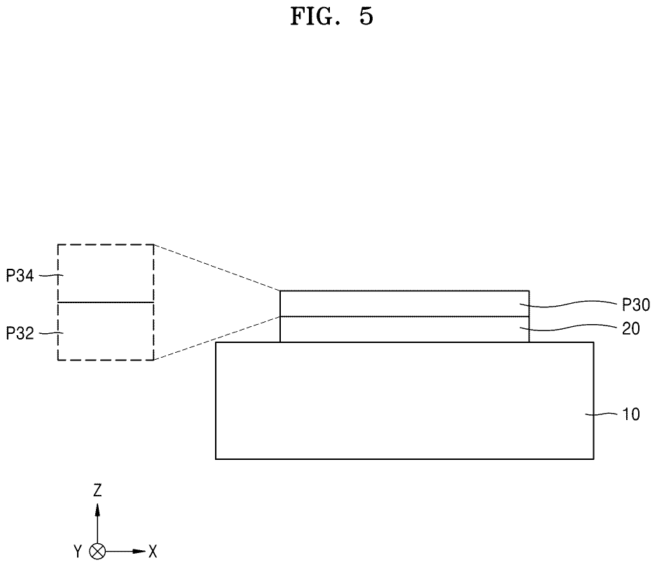

Referring to FIGS. 3 and 5, a preliminary dielectric film structure P30 including a metal oxide film P32 and a silicon oxide film P34 may be formed on the gate interface film 20. The metal oxide film P32 and the silicon oxide film P34 may each be deposited using an atomic layer deposition (ALD) process. For example, the ALD process may be performed at a temperature within a range from about 250° C. to about 350° C. and a pressure condition within a range from about 3 torr to about 6 torr.

The preliminary dielectric film structure P30 may have a thickness within a range from about 18 Å to about 40 Å in a vertical direction. A proportion of the metal oxide film P32 and a proportion of the silicon oxide film P34 in the preliminary dielectric film structure P30 may be configured in various ways. In other words, the metal oxide film P32 may be formed with a vertical thickness that is the same as or different from the vertical thickness of the silicon oxide film P34. For example, the metal oxide film P32 may be formed thicker in the vertical direction (Z direction) than the silicon oxide film P34. The metal oxide film P32 may include at least one of hafnium (Hf), zirconium (Zr), lanthanum (La), and aluminum (Al).

The preliminary dielectric film structure P30 may be formed to include various shapes of the metal oxide film P32 and the silicon oxide film P34 depending on the shapes of the first region 32 and the second region 34 of the dielectric film structure 30 to be formed. For example, the preliminary dielectric film structure P30 may be formed to include a plurality of metal oxide films P32 and/or a plurality of silicon oxide films P34 to form the dielectric film structures 30a, 30b, 30c, and 30d illustrated in FIGS. 2A to 2D.

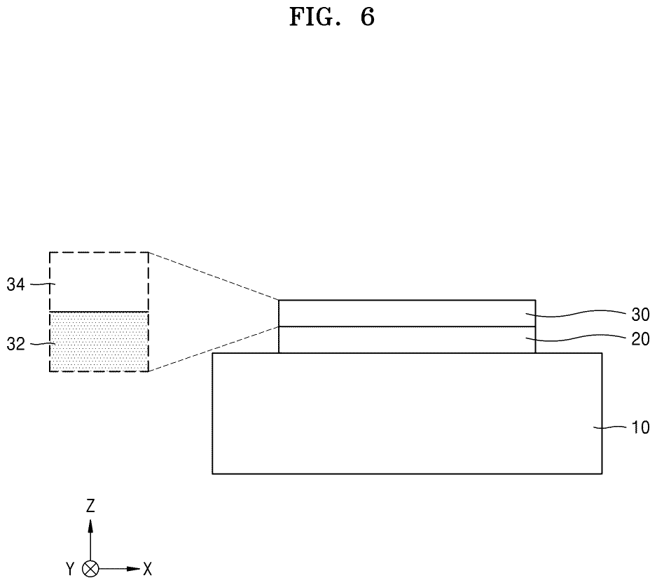

Referring to FIGS. 3 and 6, the preliminary dielectric film structure P30 of FIG. 5 may be heat-treated in a nitrogen atmosphere to form the dielectric film structure 30. For example, the preliminary dielectric film structure P30 may be heat-treated in an ammonia (NH₃) atmosphere. The heat-treatment process may be performed as a rapid thermal processing (RTP) process. In addition, the heat treatment process may be performed in a temperature range from about 650° C. to about 850° C., and after performing a heat treatment process at a first temperature, a heat treatment at a second temperature that is different from the first temperature may be performed. For example, the second temperature may be higher than the first temperature. For example, the first temperature may be within in a range from about 650° C. to about 750° C., and the second temperature may be within in a range from about 750° C. to about 850° C. The operation of heat treatment at the first temperature may be performed within a range from about 20 seconds to about 1 minute, and the operation of heat-treating at the second temperature may be performed within a range from about 0.5 seconds to about 10 seconds.

With the heat treatment process in the nitrogen atmosphere, the preliminary dielectric film structure P30 may form a dielectric film structure 30 including a metal silicon oxide, and the dielectric film structure 30 may include a first region 32 that is phase-separated and a second region 34. The first region 32 may be a crystallized region, and the second region 34 may be an amorphous region.

The first region 32 may include silicon Si at a first concentration, the second region 34 may include Si at a second concentration, and the first concentration of the first region 32 may be less than the second concentration of the second region 34. In other words, the metal concentration of the first region 32 may be greater than the metal concentration of the second region 34. For example, the first region 32 and the second region 34 may include Hf, and the concentration of Hf of the first region 32 may be greater than the concentration of Hf of the second region 34.

The first region 32 may include a crystal phase having a high dielectric constant among a plurality of crystal phases of a metal oxide at a higher ratio than a crystal phase having a low dielectric constant among the plurality of crystal phases. For example, the first region 32 may include Hf and may include a crystal phase having a high dielectric constant among the plurality of crystal phases of hafnium oxide at a higher ratio than a crystal phase having a low dielectric constant among the plurality of crystal phases. For example, the first region 32 may include a monoclinic phase (m-HfO₂), a tetragonal phase (t-HfO₂), a cubic phase (c-HfO₂), and an orthorhombic phase (o-HfO₂) of hafnium oxide, and may include a high ratio of the orthorhombic phase having ferroelectric properties and a high dielectric constant compared to the monoclinic phase, tetragonal phase, and cubic phase having relatively low dielectric constants. For example, the first region 32 may include a monoclinic phase of hafnium oxide within a range from about 60% to about 80%, and a monoclinic phase within a range from about 3% to about 10%.

Because the dielectric film structure 30 is formed by heat treatment in a nitrogen atmosphere, the dielectric film structure 30 may include nitrogen. For example, the dielectric film structure 30 may include nitrogen within an amount range of about 2 at % to about 20 at %.

At this time, as shown in FIGS. 5 and 6, the thickness of each of the metal oxide film P32 and the silicon oxide film P34 is not limited to being directly reflected as the thickness of each of the first region 32 and the second region 34.

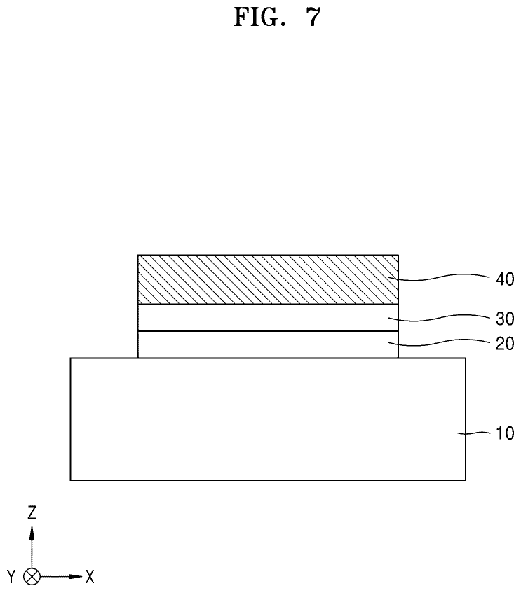

Referring to FIGS. 3 and 7, a gate electrode 40 may be formed on the dielectric film structure 30. The gate electrode 40 may include at least one of titanium nitride (TiN), tantalum carbide (TaC), tantalum nitride (TaN), titanium silicon nitride (TiSiN), tantalum silicon nitride (TaSiN), tantalum titanium nitride (TaTlN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MON), molybdenum carbide (MoC), tungsten carbide (WC), rhodium (Rh), palladium (Pd), iridium (Ir), osmium (Os), silver (Ag), gold (Au), zinc (Zn), vanadium (V), and any combination thereof.

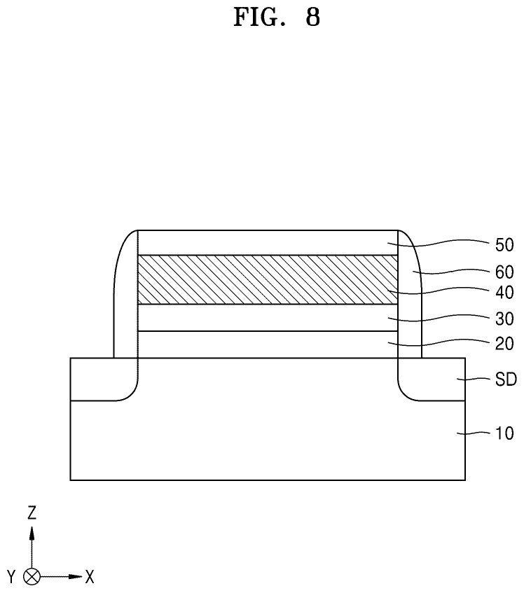

Referring to FIG. 3 and FIG. 8, a gate capping pattern 50 may be formed on the gate electrode 40. The gate capping pattern 50 may include a silicon nitride film. After forming the gate capping pattern 50, a gate spacer 60 may be formed to cover sidewalls of the gate interface film 20, the dielectric film structure 30, the gate electrode 40, and the gate capping pattern 50. The gate spacer 60 may include an oxide film, a nitride film, or any combination thereof.

Thereafter, a source/drain region SD may be formed by performing an ion implantation process on an active region (not shown) of the substrate 10 on both sides of the gate structure PGT, which is a structure in which the gate interface film 20, the dielectric film structure 30, the gate electrode 40, and the gate capping pattern 50 are stacked.

In the related art, when a dielectric film structure has an extremely small thickness, for example, about 18 Å to 40 Å, and when a dielectric film structure including a metal silicon oxide includes a metal with a relatively high content within a range from about 85% to about 100%, there is a problem that crystallization of the entire region of the dielectric film structure is induced by a subsequent heat treatment process, which results in leakage current.

According to the manufacturing method according to embodiments, even when the dielectric film structure 30 has an extremely small thickness within a range from about 18 Å to about 40 Å, the heat treatment process induces crystallization only in a part of the dielectric film structure 30 so that a phase-separated crystallized region and an amorphous region are included. Because the amorphous region blocks the flow of leakage current within the gate structure, the leakage current may be reduced or prevented.

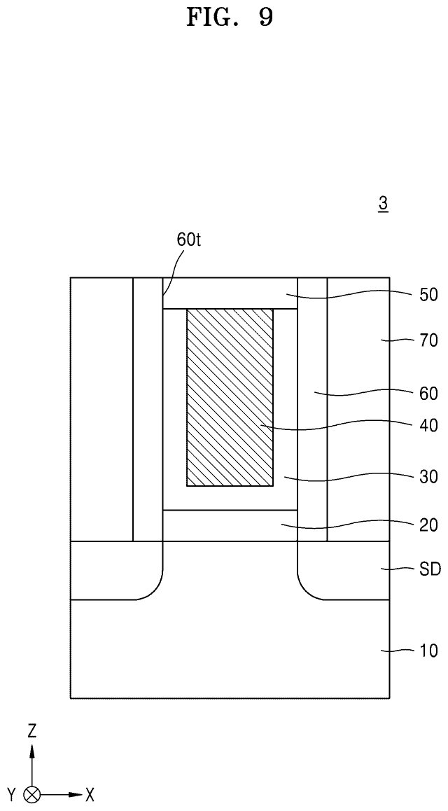

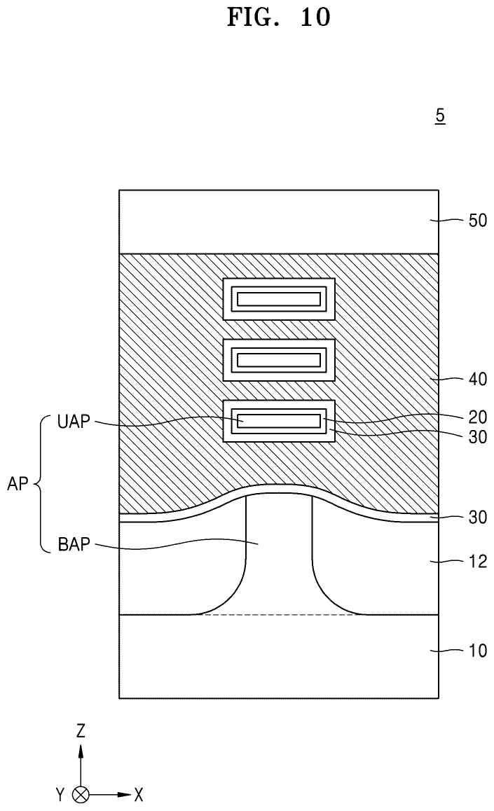

FIG. 9 is a schematic diagram illustrating a semiconductor device 3 according to embodiments. Because the semiconductor device 3 is configured substantially similar to the semiconductor device 1 illustrated in FIGS. 1A and 1B, the description of similar configurations will be omitted, and a specific description of different configurations will be provided.

Referring to FIG. 9, the semiconductor device 3 includes a substrate 10, a source/drain region SD on the substrate 10, a gate interface film 20 on the substrate 10, a dielectric film structure 30 on the gate interface film 20, a gate electrode 40 on the dielectric film structure 30, a gate capping pattern 50 on the gate electrode 40, and may include a gate spacer 60 and an interlayer insulating film 70.

The gate spacer 60 may be configured of a single layer or multiple layers, and may include, for example, an oxide film, a nitride film, or any combination thereof. Alternatively, the gate spacer 60 may include a material having etch selectivity with respect to the interlayer insulating film 70.

A sidewall of a gate trench 60t may be defined by a sidewall of the gate spacer 60, and a bottom surface of the gate trench 60t may be defined by the upper surface of the substrate 10. The gate interface film 20 may be arranged within the gate trench 60t and may cover the bottom surface of the gate trench 60t. However, depending on the method of forming the gate interface film 20, the gate interface film 20 may extend to cover the sidewall of the gate trench 60t.

The dielectric film structure 30 may be placed within the gate trench 60t and may extend to cover the sidewall of the gate trench 60t and the upper surface of the gate interface film 20. The gate electrode 40 may be arranged on the dielectric film structure 30, and side and bottom surfaces of the gate electrode 40 may be covered by the dielectric film structure 30.

The dielectric film structure 30 may be configured similarly to the dielectric film structure 30 described above with reference to FIGS. 1A and 1B, and may include the crystallized first region 32 and the amorphous second region 34.

The interlayer insulating film 70 may surround an outer wall of the gate spacer 60 and cover an upper surface of the source/drain region SD together with the gate spacer 60. The interlayer insulating film 70 may include, for example, at least one of silicon oxide, silicon nitride, silicon oxynitride, and a low-dielectric constant material. The low-dielectric constant materials may include, for example, fluorinated tetraethylorthosilicate (FTEOS), hydrogensilsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diAcetoxyditertiarybutosiloxane (DADBS), trimethylsilil phosphate (TMSP), polytetrafluoroEthylene (PTFE), tonen silazen (TOSZ), fluoride silicate glass (FSG), polyimidenanofoams such as polypropylene oxide, carbon doped silicon oxide (CDO), organo silicate glass (OSG), SiLK, amorphous fluorinated carbon, silica aerogels, silica xerogels, mesoporous silica or any combination thereof, but are not limited thereto,

FIG. 10 is a schematic diagram illustrating a semiconductor device 5 according to embodiments. For reference, the semiconductor device 5 may be a field effect transistor having a gate-all-around structure including an active region having a shape of a nanowire or nanosheet and a gate surrounding the active region. The term “nanosheet” used in the present specification may denote a conductive structure having a cross-section substantially perpendicular to a direction in which current flows. The nanosheet should be understood to include nanowires.

The semiconductor device 5 may include an active pattern AP, and the active pattern AP may include a bottom active pattern BAP and an upper active pattern UAP. The active pattern AP may include a material similar to the material forming the channel film described above with reference to FIG. 1A and FIG. 1B.

The bottom active pattern BAP may be a fin-shaped active region protruding in a vertical direction (Z direction) on the upper surface of the substrate 10. A device isolation film 12 may be arranged on a sidewall of the bottom active pattern BAP. The device isolation film 12 may cover at least a portion of the sidewall of the bottom active pattern BAP. The device isolation film 12 may include at least one of silicon nitride (SiN), silicon oxynitride (SiON), and silicon oxide (SiO₂).

The upper active pattern UAP may be configured of a plurality of pieces, the plurality of upper active patterns UAP may be spaced apart from the bottom active pattern BAP in the vertical direction (Z direction), and each of the plurality of upper active patterns UAP may also be spaced apart from each other in the vertical direction (Z direction).

Each of the plurality of upper active patterns UAPs may function as a channel region and may have a vertical thickness selected from a range of about 4 nm to about 6 nm but is not limited thereto. Each of the plurality of upper active patterns UAPs may have substantially the same thickness in the vertical direction (Z direction) or may have different thicknesses. Each of the plurality of upper active patterns UAPs may be formed to have substantially the same size or may be formed to have different sizes. The plurality of upper active patterns UAPs may include three upper active patterns UAPs, as illustrated in FIG. 10, but is not limited thereto, and may include at least one upper active pattern UAP.

Each of the plurality of upper active patterns UAPs may be surrounded by the gate interface film 20, the gate interface film 20 may be surrounded by the dielectric film structure 30, and the dielectric film structure 30 may be surrounded by the gate electrode 40. The dielectric film structure 30 may extend to cover an upper surface of the device isolation film 12 and an upper surface of the bottom active pattern BAP, and the dielectric film structure 30 may be disposed between the gate electrode 40, the device isolation film 12, and the bottom active pattern BAP.

The dielectric film structure 30 may be configured similarly to the dielectric film structure 30 described above with reference to FIG. 1A and FIG. 1B, and may include the crystallized first region 32 and the amorphous second region 34.

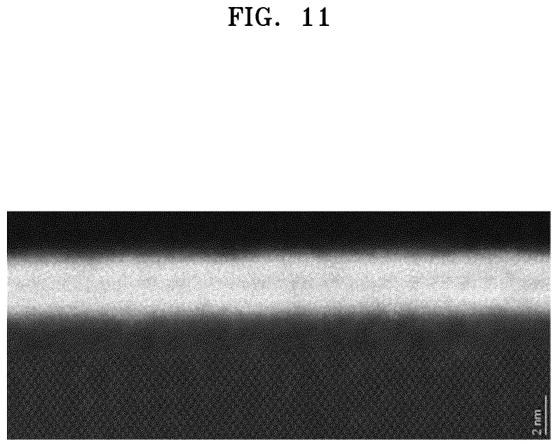

FIG. 11 is a scanning transmission electron microscopy-high-angle annular dark field (STEM-HAADF) image of a dielectric film structure of the disclosed concepts.

Referring to FIG. 11, the dielectric film structure indicated by a light shade may be confirmed on a silicon substrate and an interface film indicated by a dark shade. It may be confirmed that the dielectric film structure is distinguished into a relatively dark shaded amorphous region and a relatively light shaded crystallized region.

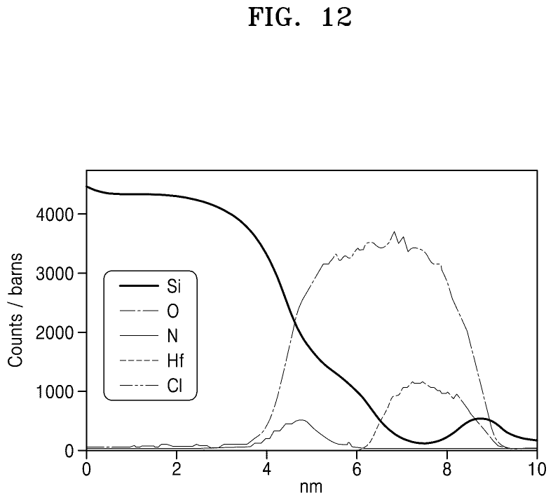

FIG. 12 is a graph showing the results of electron energy loss spectroscopy (EELS) analysis of an electron microscope (TEM) image of a semiconductor device of the disclosed concepts.

Referring to FIG. 12, within the semiconductor device, an element composition ratio according to a position range in the thickness direction (vertical direction) of the semiconductor device may be confirmed. Specifically, it may be confirmed that Si occupies a high composition ratio within the position range of 0 nm to 4 nm where the substrate is located, and it may be confirmed that Si and oxygen (O) occupy relatively high composition ratios within the position range of 4 nm to 6 nm where the gate interface film is located. In addition, it may be confirmed that Si occupies a relatively low composition ratio in the crystallization region of 6 nm to 8 nm, and Hf occupies a relatively high composition ratio. It may be confirmed that Si occupies a relatively high composition ratio in the non-crystallization region of 8 nm to 10 nm compared to the crystallization region, and Hf occupies a relatively low composition ratio.

Accordingly, even if a dielectric film structure having a thickness of 18 Å to 40 Å in the vertical direction is formed according to the manufacturing method of the disclosed concepts, it may be confirmed that phase separation occurs, and thus, a non-crystallization region and a crystallization region are formed.

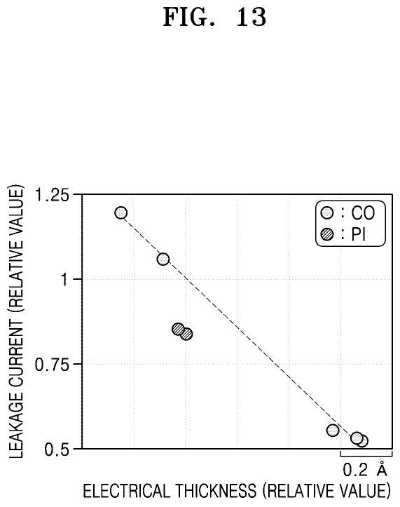

FIG. 13 is a graph comparing the leakage current characteristics of a semiconductor device of the disclosed concepts with a semiconductor device of a comparative example.

Referring to FIG. 13, a relative value of leakage current of the semiconductor device PI of the disclosed concepts and a relative value of leakage current of a semiconductor device CO according to the comparative example are each displayed as the relative value of the electrical thickness. The semiconductor device CO as a comparative example includes a dielectric film structure, and in order to form the dielectric film structure, a preliminary dielectric film structure is formed by alternately stacking a metal oxide film and a silicon oxide in a cross-sectional manner, and the preliminary dielectric film structure is nitrided with nitrogen plasma (N₂), and then heat-treated in an oxygen atmosphere at a relatively high temperature of about 900° C. to about 1,100° C. for about 1 second to about 3 seconds to form a dielectric film structure.

It may be confirmed that the semiconductor device PI of the disclosed concepts has a leakage current reduced by about 16% at the same electrical thickness compared to the semiconductor device CO as a comparative example. Therefore, it may be confirmed that the dielectric film structure included in the semiconductor device manufactured by the manufacturing method of the disclosed concepts has a leakage current reduction effect.

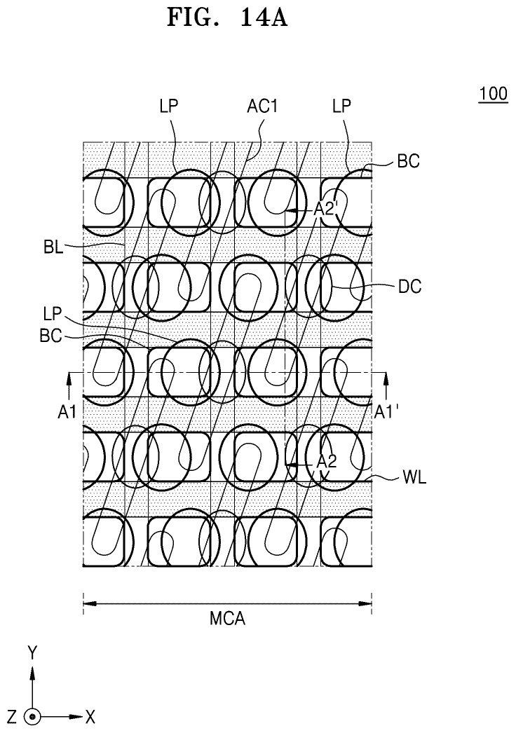

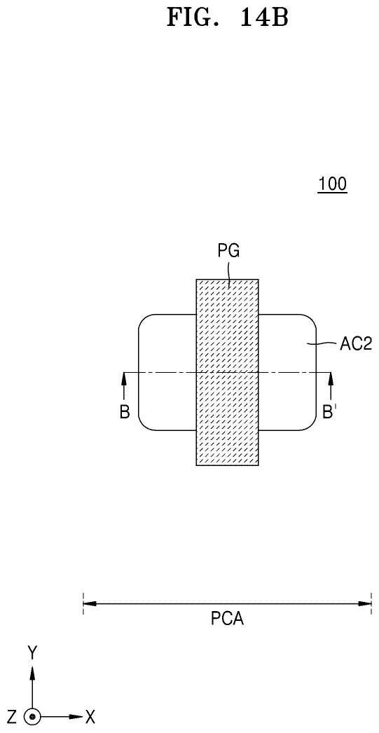

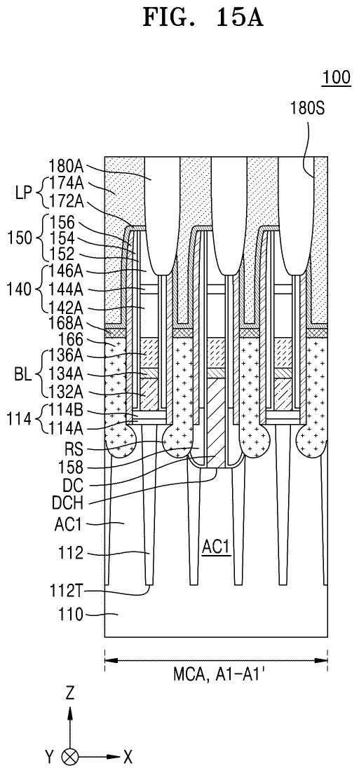

FIGS. 14A and 14B are layout diagrams showing a semiconductor device 100 according to embodiments.

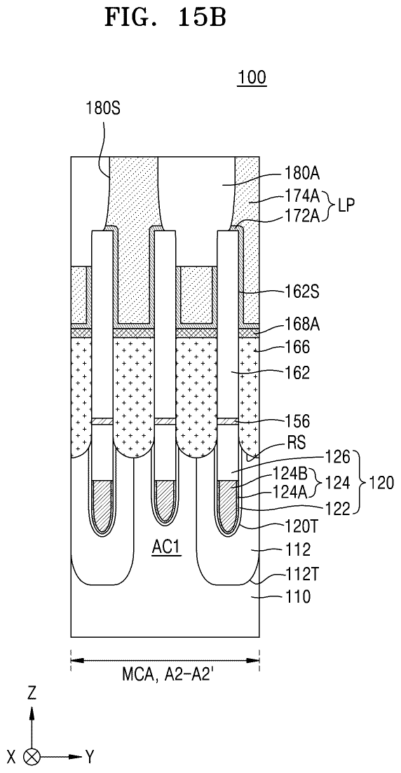

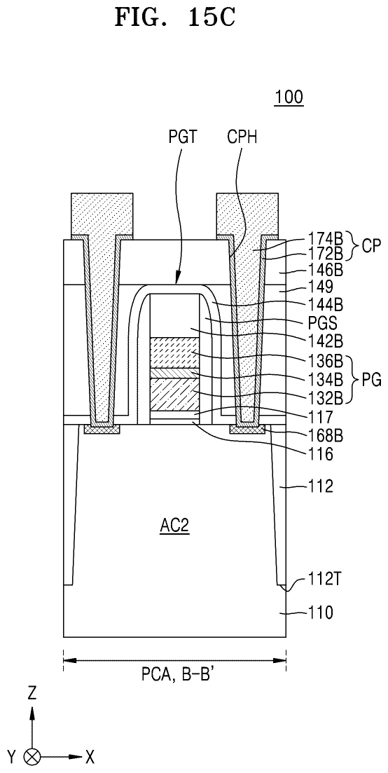

FIG. 15A is a cross-sectional view taken along line A1-A1′ of FIG. 14A.

FIG. 15B is a cross-sectional view taken along line A2-A2′ of FIG. 14A.

FIG. 15C is a cross-sectional view taken along line B-B′ of FIG. 14B.

Referring to FIGS. 14A to 15C, the semiconductor device 100 may include a substrate 110 including a cell array region MCA and a peripheral circuit region PCA. A device isolation trench 112T may be formed in the substrate 110, and a device isolation film 112 may be formed within the device isolation trench 112T. In the cell array region MCA, a plurality of first active regions AC1 may be defined on the substrate 110 by the device isolation film 112, and in the peripheral circuit region PCA, a second active region AC2 may be defined on the substrate 110.

The plurality of first active regions AC1 may be arranged to have their long axes in a diagonal direction with respect to the first horizontal direction (X direction) and the second horizontal direction (Y direction), respectively. A plurality of word lines WL may extend in parallel with each other in the first horizontal direction (X direction) across the plurality of first active regions AC1. A plurality of bit lines BL may extend in parallel with each other in the second horizontal direction (Y direction) above the plurality of word lines WL. The plurality of bit lines BL may be connected to the plurality of first active regions AC1 through a plurality of direct contacts DC.

A plurality of buried contacts BC may be formed between two adjacent bit lines BL among the plurality of bit lines BL. The plurality of buried contacts BC may be arranged in a row in the first horizontal direction (X direction) and the second horizontal direction (Y direction). A plurality of landing pads LP may be formed over the plurality of buried contacts BC. The plurality of buried contacts BC and the plurality of landing pads LP may connect a lower electrode (not shown) of a capacitor formed on an upper portion of the plurality of bit lines BL to the first active region AC1. The plurality of landing pads LP may be arranged to overlap each of the buried contacts BC.

The substrate 110 may include silicon, for example, single crystal silicon, polycrystalline silicon, or amorphous silicon. In some embodiments, the substrate 110 may include at least one selected from Ge, SiGe, SiC, GaAs, InAs, and InP. In some embodiments, the substrate 110 may include a conductive region, for example, a well doped with an impurity, or a structure doped with an impurity. The device isolation film 112 may include an oxide film, a nitride film, or any combination thereof.

In the cell array region MCA, a plurality of word line trenches 120T extending in the first horizontal direction (X direction) are formed in the substrate 110, and a plurality of buried gate structures 120 may be arranged within the plurality of word line trenches 120T. Each of the plurality of buried gate structures 120 may include a gate dielectric film 122, a buried gate electrode 124, and a gate capping pattern 126.

The buried gate electrode 124 included in the plurality of buried gate structures 120 may correspond to the plurality of word lines WL illustrated in FIG. 14A. The gate dielectric film 122 may include a silicon oxide film, a silicon nitride film, a silicon oxynitride film, an oxide/nitride/oxide (ONO) film, or a high-k dielectric film having a higher dielectric constant than the silicon oxide film. In some embodiments, although not illustrated, the gate dielectric film 122 may be configured to include the gate interface film 20 and the dielectric film structure 30 described above with reference to FIGS. 1A and 1B.

The buried gate electrode 124 may include a work function control layer 124A conformally arranged on a lower inner wall of the plurality of word line trenches 120T and a buried conductive layer 124B filling the lower inner wall of the plurality of word line trenches 120T. For example, the work function control layer 124A may include a metal, metal nitride, or metal carbide such as Ti, TiN, TiAlN, TiAlC, TiAlCN, TiSiCN, Ta, TaN, TaAlN, TaAlCN, TaSiCN, and the buried conductive layer 124B may include at least one of W, WN, TiN, TaN, and doped polysilicon. The gate capping pattern 126 may include a silicon oxide film, a silicon nitride film, a silicon oxynitride film, or any combination thereof.

A buffer film 114 may be formed on the substrate 110 in the cell array region MCA. The buffer film 114 may include a first insulating film 114A and a second insulating film 114B. The first insulating film 114A and the second insulating film 114B may each include an oxide film, a nitride film, or a combination thereof.

The plurality of direct contacts DC may be formed within a plurality of direct contact holes DCH on the substrate 110. The plurality of direct contacts DC may be connected to the plurality of first active regions AC1. The plurality of direct contacts DC may include doped polysilicon. For example, the plurality of direct contacts DC may include polysilicon including a relatively high concentration of n-type impurities such as phosphorus (P), arsenic (As), bismuth (Bi), and antimony (Sb).

The plurality of bit lines BL may extend in the second horizontal direction (Y direction) over the substrate 110 and the plurality of direct contacts DC. The plurality of bit lines BL may be connected to the first active region AC1 through the direct contacts DC. The plurality of bit lines BL may each include a lower conductive pattern 132A, an intermediate conductive pattern 134A, and an upper conductive pattern 136A sequentially stacked on the substrate 110. The lower conductive pattern 132A may include doped polysilicon. The intermediate conductive pattern 134A and the upper conductive pattern 136A may each include TIN, TiSiN, W, tungsten silicide, or any combination thereof. In embodiments, the intermediate conductive pattern 134A may include TiN, TiSiN, or any combination thereof, and the upper conductive pattern 136A may include W.

The plurality of bit lines BL may each be covered by a plurality of insulating capping structures 140. Each of the plurality of insulating capping structures 140 may include a lower capping pattern 142A, an insulating layer pattern 144A, and an upper capping pattern 146A. The lower capping pattern 142A, the insulating layer pattern 144A, and the upper capping pattern 146A may include a silicon nitride film. The plurality of insulating capping structures 140 may extend in the second horizontal direction (Y direction) on the plurality of bit lines BL.

A spacer structure 150 may be arranged on both sidewalls of each of the plurality of bit lines BL. The spacer structure 150 may extend in the second horizontal direction (Y direction) on the both sidewalls of the plurality of bit lines BL, and a portion of the spacer structure 150 may extend into the interior of the direct contact hole DCH to cover both sidewalls of the direct contact DC.

In some embodiments, the spacer structure 150 may include a first spacer layer 152, a second spacer layer 154, and a third spacer layer 156. The first spacer layer 152 is conformally arranged on the sidewalls of the plurality of bit lines BL, the sidewall of an insulating capping structure 140, and an inner wall of the direct contact hole DCH. The second spacer layer 154 and the third spacer layer 156 may be sequentially arranged on the first spacer layer 152. In some embodiments, the first spacer layer 152 and the third spacer layer 156 may include silicon nitride, and the second spacer layer 154 may include silicon oxide. In some embodiments, the first spacer layer 152 and the third spacer layer 156 may include silicon nitride, and the second spacer layer 154 may include air or a low-k dielectric material. Here, the term “air” may refer to a space including other gases that may be present in the atmosphere or during a manufacturing process.

A buried insulating layer 158 may surround a lower sidewall of the direct contact DC on the first spacer layer 152 and may fill the remaining space of the direct contact hole DCH. The buried insulating layer 158 may include silicon nitride, silicon oxynitride, silicon oxide, or any combination thereof.

The direct contact DC is formed within the direct contact hole DCH formed in the substrate 110 and may extend to a level higher than the upper surface of the substrate 110. For example, an upper surface of the direct contact DC may be placed at the same level as an upper surface of the lower conductive pattern 132A, and the upper surface of the direct contact DC may be in contact with a bottom surface of the intermediate conductive pattern 134A. In addition, a bottom surface of the direct contact DC may be arranged at a level lower than the upper surface of the substrate 110.

A plurality of insulating fences 162 and a plurality of conductive plugs 166 may be arranged in a row in the second horizontal direction (Y direction) between each of the plurality of bit lines BL. The plurality of insulating fences 162 may be arranged on the gate capping pattern 126 arranged on an upper side of the plurality of word line trenches 120T and may have an upper surface arranged at the same level as the upper surface of the insulating capping structure 140. The plurality of conductive plugs 166 may extend lengthwise in the vertical direction (Z direction) from a recessed space RS formed in the substrate 110. In the second horizontal direction (Y direction), both sidewalls of each of the plurality of conductive plugs 166 may be mutually insulated by the plurality of insulating fences 162. The plurality of insulating fences 162 may include a silicon nitride film. The plurality of conductive plugs 166 may form a plurality of buried contacts BC, as illustrated in FIG. 14A.

A plurality of metal silicide films 168A and the plurality of landing pads LP may be formed on the plurality of conductive plugs 166. The metal silicide films 168A and the landing pads LP may be arranged to vertically overlap with the conductive plugs 166. The metal silicide films 168A may include cobalt silicide, nickel silicide, or manganese silicide. The plurality of landing pads LP may each be connected to the conductive plugs 166 through the metal silicide films 168A.

The plurality of landing pads LP may each include a conductive barrier film 172A and a landing pad conductive layer 174A. The conductive barrier film 172A may include Ti, TiN, or any combination thereof. The landing pad conductive layer 174A may include a metal, a metal nitride, conductive polysilicon, or any combination thereof. For example, the landing pad conductive layer 174A may include W. The plurality of landing pads LP may have a plurality of island-like pattern shapes in a plan view.

The plurality of landing pads LP may be electrically insulated from each other by an insulating pattern 180 that fills an insulating space 180S around the plurality of landing pads LP. The insulating pattern 180 may fill an insulating space 180S disposed between the bit line BL and a conductive plug 166, and may cover both sidewalls of the insulating capping structure 140.

In some embodiments, the insulating pattern 180 may include silicon nitride, silicon oxynitride, silicon oxide, or any combination thereof. In some embodiments, the insulating pattern 180 may be formed as a two-layer structure of a first material layer (not shown) and a second material layer (not shown), wherein the first material layer may include a low-k material such as SiO₂, SiOCH, or SiOC, and the second material layer may include silicon nitride or silicon oxynitride.

A peripheral circuit gate structure PGT may be formed on a second active region AC2 in a peripheral circuit region PCA. The peripheral circuit gate structure PGT may include a gate interface film 116, a dielectric film structure 117, a peripheral circuit gate electrode PG, and a gate capping pattern 142B sequentially stacked on the second active region AC2.

The gate interface film 116 may include silicon oxide, silicon nitride, silicon oxynitride, oxide/nitride/oxide (ONO), or any combination thereof.

The dielectric film structure 117 may include a metal silicon oxide. For example, the metal silicon oxide may include at least one of hafnium (Hf), zirconium (Zr), lanthanum (La), and aluminum (Al). The dielectric film structure 117 may include the first region 32 (refer to FIG. 1B) and the second region 34 (refer to FIG. 1B) that are phase-separated into a crystallized region and an amorphous region of metal silicon oxide. The dielectric film structure 117 is configured in a substantially similar manner to the dielectric film structure 30 described above with reference to FIGS. 1A and 1B, and thus, the detailed description thereof will be omitted.

The peripheral circuit gate electrode PG may include a lower conductive pattern 132B, an intermediate conductive pattern 134B, and an upper conductive pattern 136B. The constituent materials of each of the lower conductive pattern 132B, the intermediate conductive pattern 134B, and the upper conductive pattern 136B may be identical to the constituent materials of the lower conductive pattern 132A, the intermediate conductive pattern 134A, and the upper conductive pattern 136A included in the bit line BL in the cell array region MCA. The gate capping pattern 142B may include a silicon nitride film.

Both sidewalls of the peripheral circuit gate structure PGT may be covered with a gate spacer PGS. The gate spacer PGS may include an oxide film, a nitride film, or any combination thereof. The peripheral circuit gate structure PGT and the gate spacer PGS may be covered with a passivation film 144B. The passivation film 144B may include a silicon nitride layer. An interlayer insulating film 149 may be formed around the peripheral circuit gate structure PGT over the passivation film 144B. The interlayer insulating film 149 may include, but is not limited to, Tonen SilaZene (TOSZ). The peripheral circuit gate structure PGT, the passivation film 144B, and the interlayer insulating film 149 may be covered with an upper insulating capping layer 146B. The upper insulating capping layer 146B may include a silicon nitride layer.

In the peripheral circuit region PCA, a contact plug CP that extends vertically through the upper insulating capping layer 146B, the interlayer insulating film 149, and the passivation film 144B to the second active region AC2 of the substrate 110 may be formed. The contact plug CP may include a conductive barrier film 172B and a landing pad conductive layer 174B similar to the plurality of landing pads LP formed in the cell array region MCA. A metal silicide film 168B may be disposed between the second active region AC2 and the contact plug CP. The metal silicide film 168B may include cobalt silicide, nickel silicide, or manganese silicide.

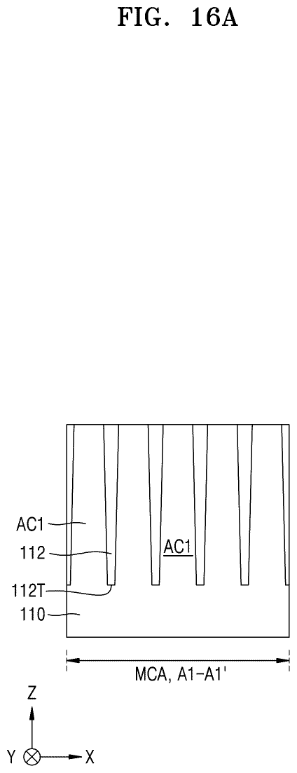

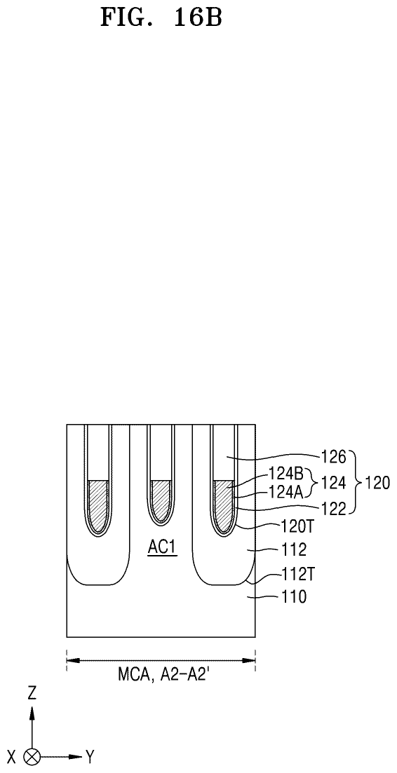

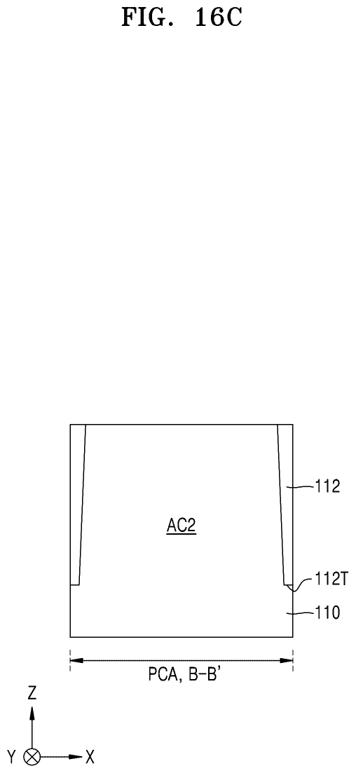

FIGS. 16A to 28C are cross-sectional views illustrating a process sequence for explaining a method of manufacturing a semiconductor device, according to embodiments. Specifically, FIGS. 16A to 28A are cross-sectional views corresponding to a cross-section along line A1-A1′ of FIG. 14A, FIGS. 16B to 28B are cross-sectional views corresponding to a cross-section along line A2-A2′ of FIG. 14A, and FIGS. 16C to 28C are cross-sectional views corresponding to a cross-section along line B-B′ of FIG. 14B.

Referring to FIGS. 16A to 16C, a plurality of device isolation trenches 112T and a plurality of device isolation films 112 are formed in a substrate 110 having a cell array region MCA and a peripheral circuit region PCA, to define a plurality of first active regions AC1 in the cell array region MCA of the substrate 110 and define a second active region AC2 in the peripheral circuit region PCA.

A plurality of word line trenches 120T extending in parallel to each other on the substrate 110 may be formed in the cell array region MCA. After cleaning the resultant product in which the plurality of word line trenches 120T are formed, a plurality of gate dielectric films 122, a plurality of gate electrodes 124, and a plurality of gate capping patterns 126 may be sequentially formed in the plurality of word line trenches 120T. In the plurality of first active regions AC1, a plurality of source/drain regions (not shown) may be formed on an upper side of the plurality of first active regions AC1 by injecting impurity ions into both sides of the plurality of gate electrodes.

The plurality of gate electrodes 124 may include a work function control layer 124A and a buried conductive layer 124B arranged on inner walls of the plurality of word line trenches 120T. For example, the plurality of gate electrodes 124 may be formed by sequentially forming the work function control layer 124A and the buried conductive layer 124B on the inner walls of the plurality of word line trenches 120T, and removing portions of the work function control layer 124A and the buried conductive layer 124B arranged on the upper side of the inner walls of the word line trenches 120T by using an etch-back process.

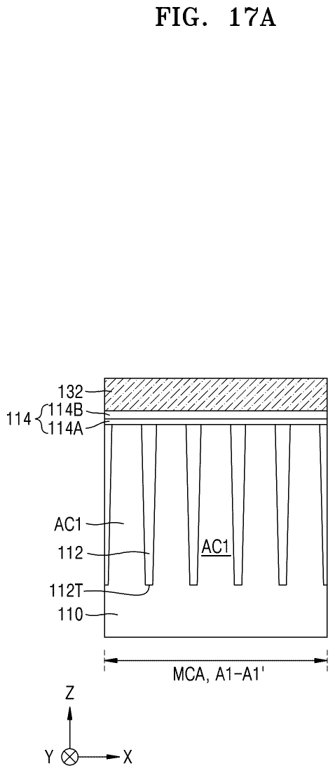

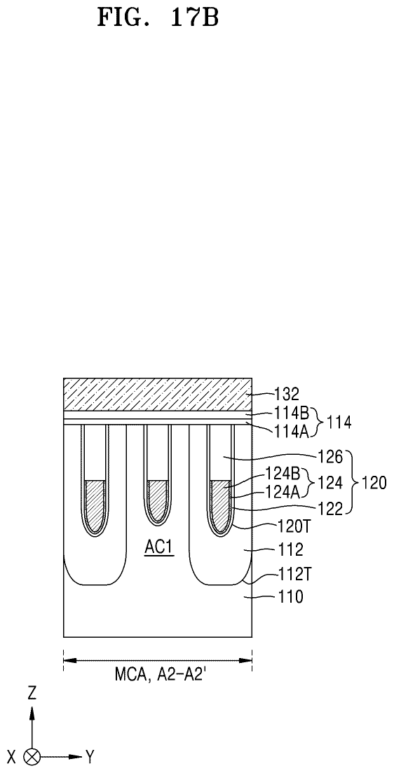

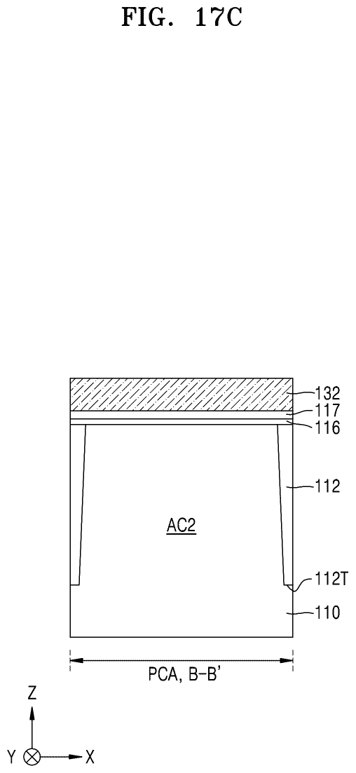

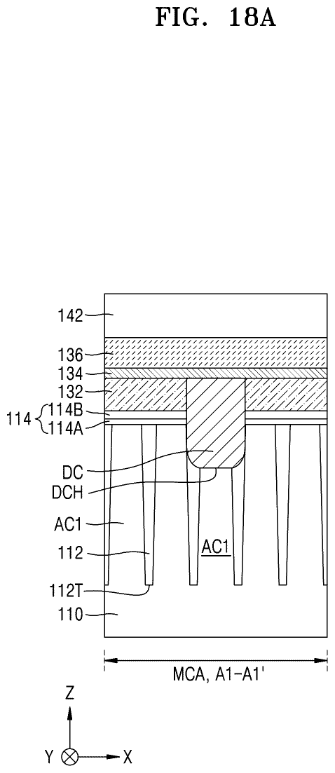

Referring to FIGS. 17A to 17C, a buffer film 114 including a first insulating film 114A and a second insulating film 114B may be formed on the substrate 110 in the cell array region MCA, and a gate interface film 116 and a dielectric film structure 117 may be formed on the substrate 110 in the peripheral circuit region PCA. The process of forming the dielectric film structure 117 may follow the process of forming a preliminary dielectric film structure P30 by depositing a metal oxide film P32 and a silicon oxide film P34, as described above with reference to FIGS. 5 and 6, and then, performing a heat treatment in a nitrogen atmosphere to form the dielectric film structure 30. Because the specific process conditions for forming the dielectric film structure 117 are similar to those described above with reference to FIGS. 5 and 6, a specific description will be omitted.

Thereafter, a lower conductive layer 132 may be formed on the buffer film 114 of the cell array region MCA and the dielectric film structure 117 of the peripheral circuit region PCA. In some embodiments, the lower conductive layer 132 may include Si, Ge, W, WN, Co, Ni, Al, Mo, Ru, Ti, TiN, Ta, TaN, Cu, or any combination thereof. For example, the lower conductive layer 132 may include polysilicon.

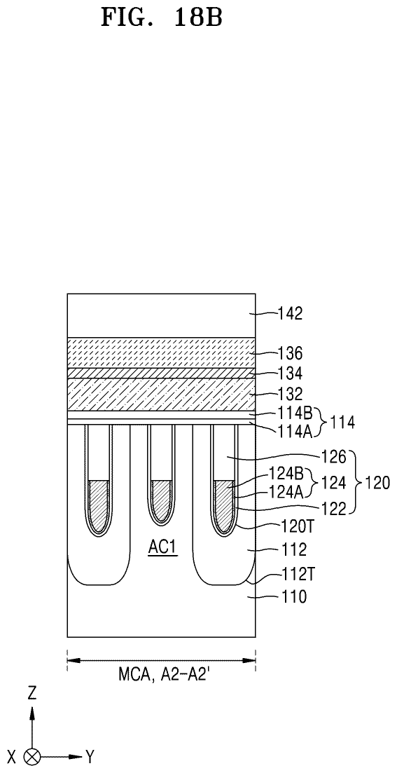

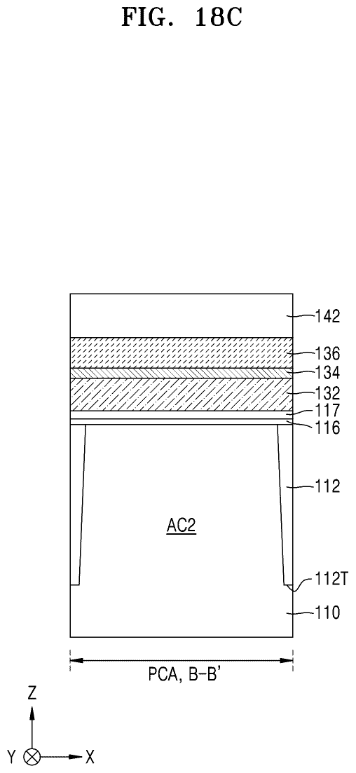

Referring to FIGS. 18A to 18C, after a first mask pattern (not shown) is formed on the lower conductive layer 132, the lower conductive layer 132 exposed through an opening (not shown) of the first mask pattern in the cell array region MCA is etched, and a direct contact hole DCH exposing the first active region AC1 of the substrate 110 may be formed by etching a portion of the substrate 110 and a portion of the device isolation film 112 exposed as a result of etching the lower conductive layer 132.

Thereafter, the first mask pattern is removed, and a direct contact DC is formed in the direct contact hole DCH. In an example process of forming the direct contact DC, a conductive layer having a thickness sufficient to fill the direct contact hole DCH is formed on an inside of the direct contact hole DCH and on top of the lower conductive layer 132, and the conductive layer may be etched back so that the conductive layer remains only within the direct contact hole DCH. The conductive layer may include polysilicon.

Thereafter, an intermediate conductive layer 134, an upper conductive layer 136, and a lower capping layer 142 may be sequentially formed on top of the lower conductive layer 132 and the direct contact DC in the cell array region MCA and the peripheral circuit region PCA. The intermediate conductive layer 134 and the upper conductive layer 136 may each include TiN, TiSiN, W, tungsten silicide, or any combination thereof. The lower capping layer 142 may include a silicon nitride film.

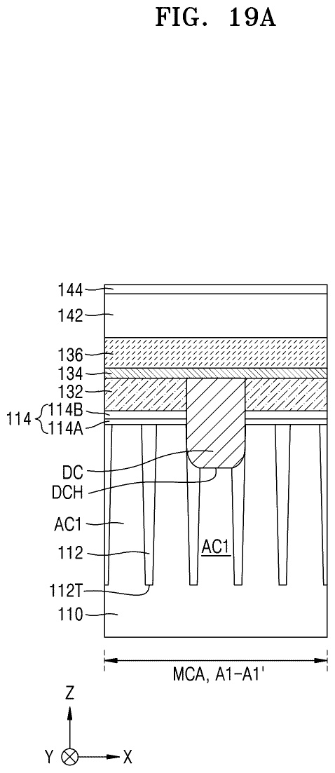

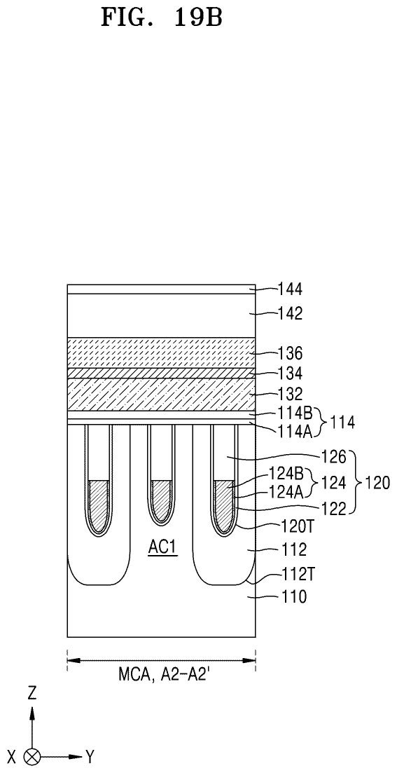

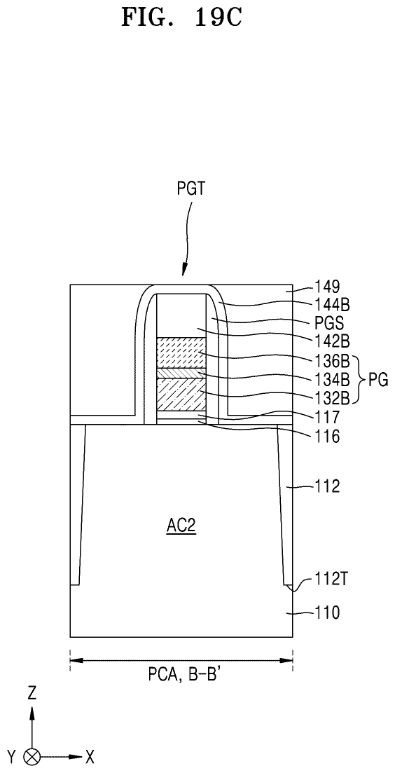

Referring to FIGS. 19A to 19C, while covering the cell array region MCA with a mask pattern (not shown), the gate interface film 116, the dielectric film structure 117, the lower conductive layer 132, the intermediate conductive layer 134, the upper conductive layer 136, and the lower capping layer 142 are patterned in the peripheral circuit region PCA, and thus, a gate electrode PG including a lower conductive pattern 132B, an intermediate conductive pattern 134B, and an upper conductive pattern 136B on the dielectric film structure 117, and a gate capping pattern 142B covering the gate electrode PG are formed. Afterwards, a gate spacer PGS is formed on both sidewalls of a peripheral circuit gate structure PGT including a stacked structure of the gate interface film 116, the dielectric film structure 117, the gate electrode PG, and the gate capping pattern 142B, and an ion implantation process is performed to form a source/drain region in a second active region AC2 on both sides of the peripheral circuit gate structure PGT.

Afterwards, the mask pattern covering the cell array region MCA is removed to expose the lower capping layer 142 in the cell array region MCA, and an insulating layer 144 covering the lower capping layer 142 in the cell array region MCA and covering the peripheral circuit gate structure PGT and the gate spacer PGS in the peripheral circuit region PCA may be formed. Afterwards, an interlayer insulating film 149 is formed to fill a space around the peripheral circuit gate structure PGT in the peripheral circuit region PCA.

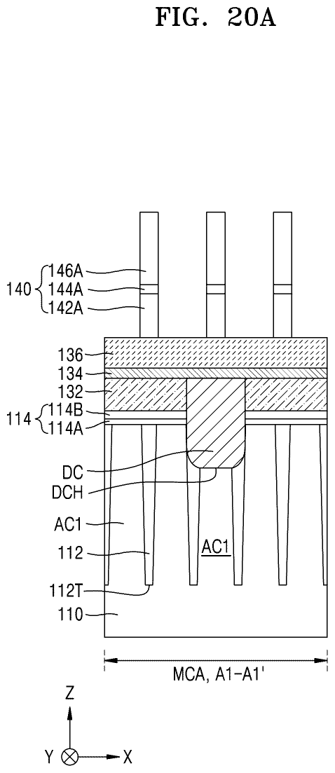

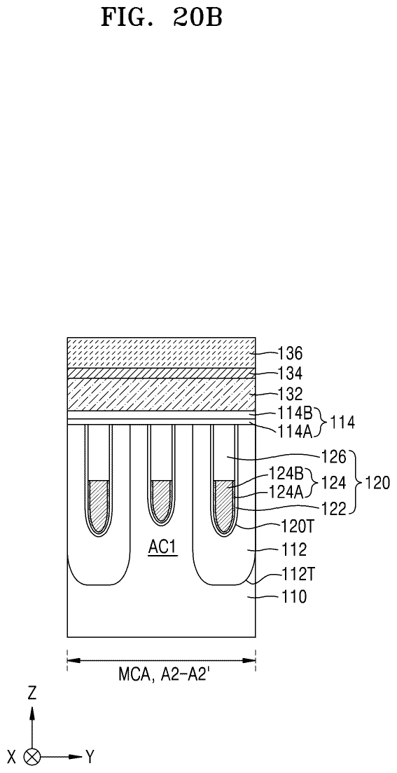

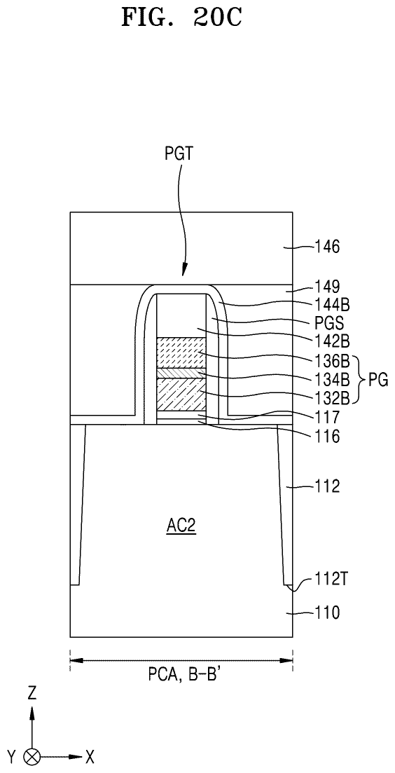

Referring to FIGS. 20A to 20C, an upper insulating capping layer 146 is formed to cover the insulating layer 144 and the interlayer insulating film 149 in the peripheral circuit region PCA and to cover the insulating layer 144 in the cell array region MCA.

Thereafter, a mask pattern (not shown) is formed on the peripheral circuit region PCA, and the upper insulating capping layer 146, the insulating layer 144, and the lower capping layer 142 are patterned in the cell array region MCA, thereby forming a lower capping pattern 142A, an insulating layer pattern 144A, and an upper capping pattern 146A that are sequentially stacked on the upper conductive layer 136. Here, the lower capping pattern 142A, the insulating layer pattern 144A, and the upper capping pattern 146A are referred to as an insulating capping structure 140.

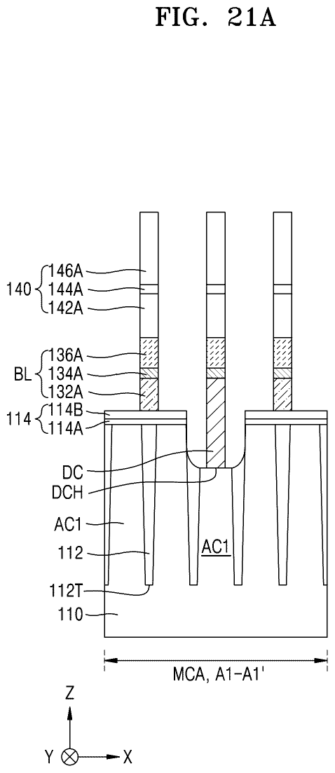

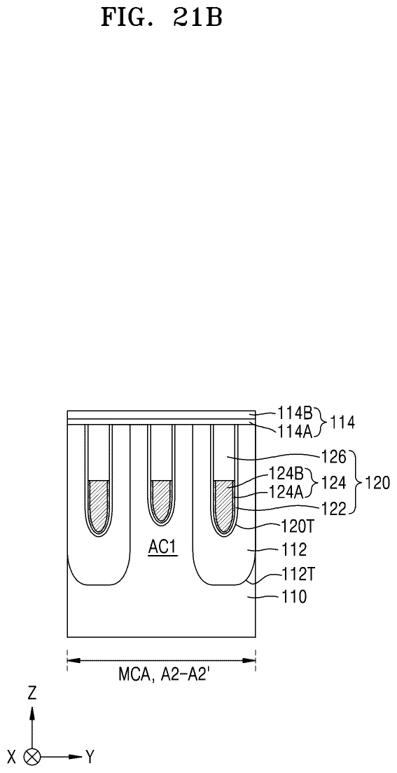

Referring to FIGS. 21A and 21B, the upper conductive layer 136, the intermediate conductive layer 134, and the lower conductive layer 132 are etched using the lower capping pattern 142A, the insulating layer pattern 144A, and the upper capping pattern 146A as etching masks in the cell array region MCA, thereby forming a plurality of bit lines BL composed of the lower conductive pattern 132B, the intermediate conductive pattern 134B, and the upper conductive pattern 136B.

In the process of forming the plurality of bit lines BL, a portion of a sidewall of the direct contact DC may be removed and a portion of the direct contact hole DCH may be exposed.

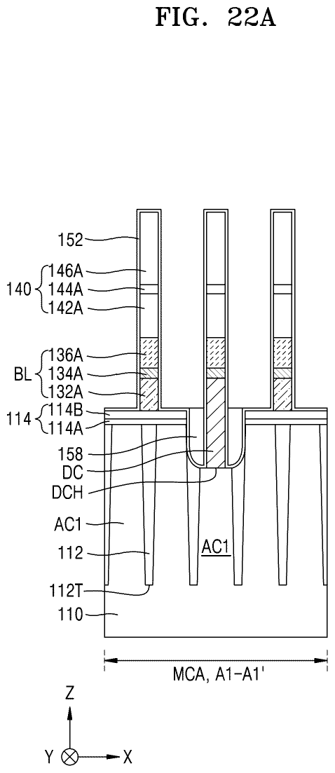

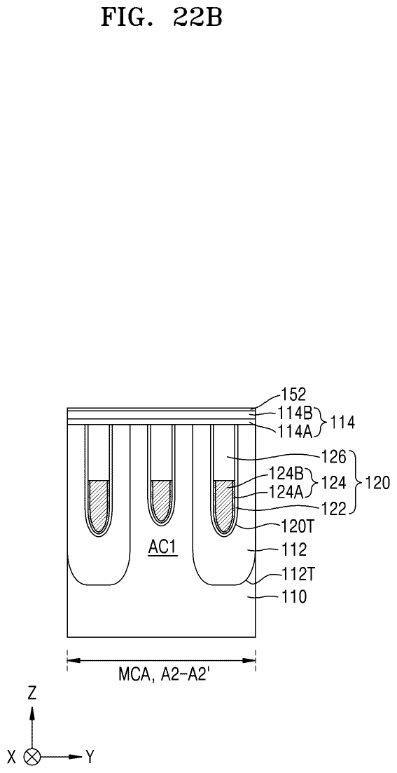

Referring to FIGS. 22A and 22B, a first spacer layer 152 may be formed on the sidewalls of the plurality of bit lines BL and the sidewalls of the direct contact DC. Thereafter, an insulating layer (not shown) may be formed on the sidewalls of the plurality of bit lines BL and the sidewalls of the direct contact DC with a thickness sufficient to fill the inside of the direct contact hole DCH, and then, an anisotropic etching process may be performed on the insulating layer to leave a buried insulating layer 158 that fills the inside of the direct contact hole DCH.

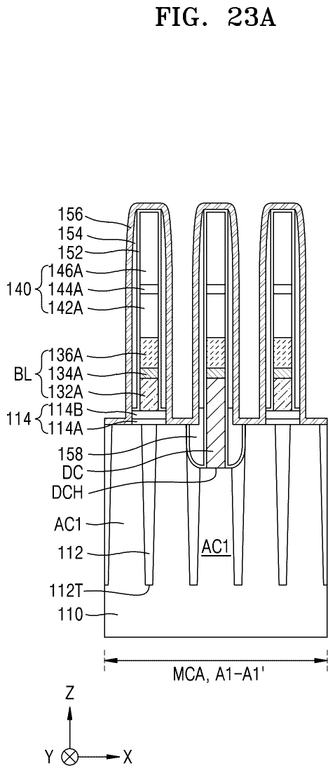

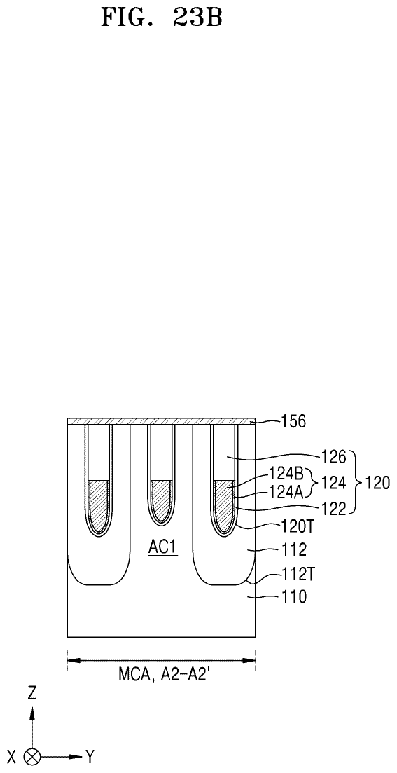

Referring to FIGS. 23A and 23B, a second spacer layer 154 covering the first spacer layer 152 may be formed on the sidewalls of the plurality of bit line BL. The second spacer layer 154 may be used as an etching mask to remove a portion of the buffer film 114 disposed between the plurality of bit lines BL and expose the upper surface of the substrate 110. At this time, a portion of the buried insulating layer 158 may also be removed.

Thereafter, a third spacer layer 156 may be formed on the sidewalls of the plurality of bit lines BL and the upper surface of the substrate 110.

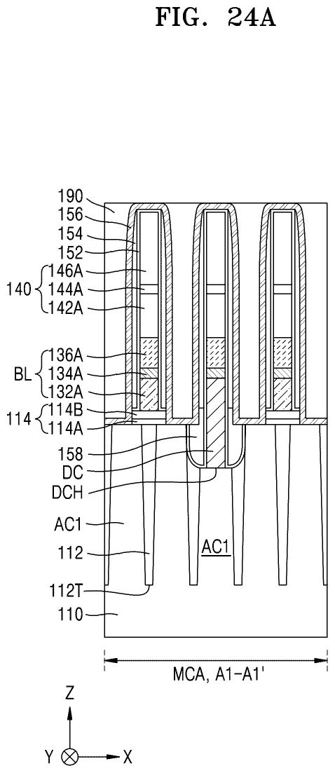

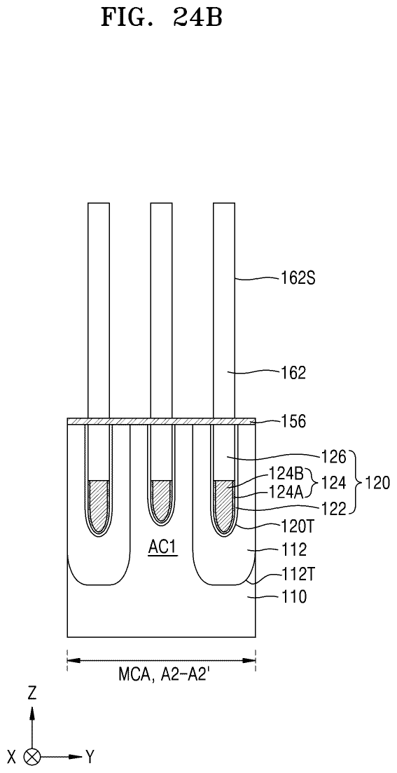

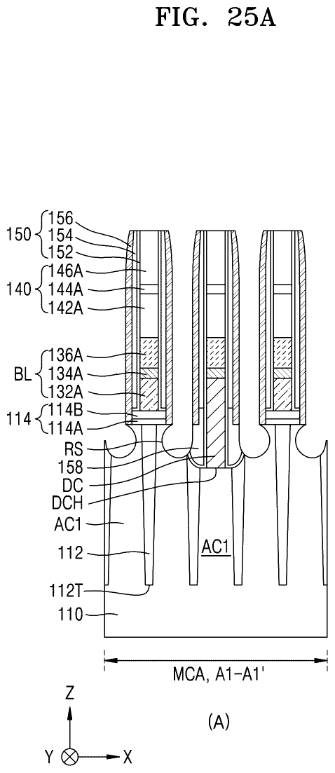

Referring to FIGS. 24A and 24B, a plurality of insulating fences 162 may be formed between each of the plurality of bit lines BL in the cell array region MCA. For example, the plurality of insulating fences 162 may be formed to vertically overlap the plurality of word line trenches 120T, and upper surfaces of the plurality of insulating fences 162 may be at the same level as an upper surface of the third spacer layer 156.

The plurality of insulating fences 162 may be arranged to be spaced apart in the second horizontal direction (Y direction), so a contact space 162S may be defined between two adjacent insulating fences 162 among the plurality of insulating fences 162 and between two bit lines BL.

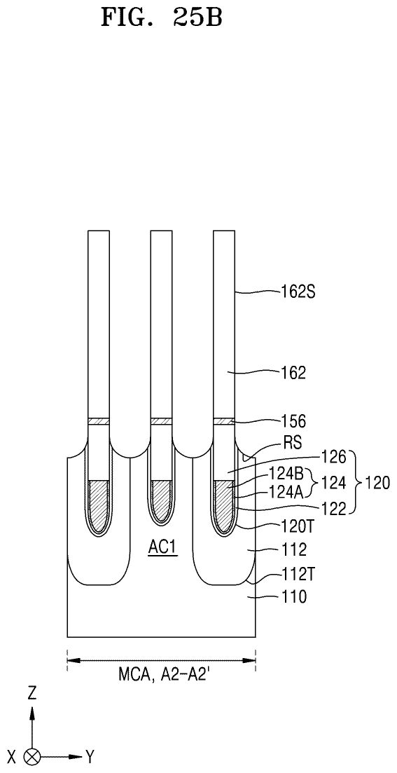

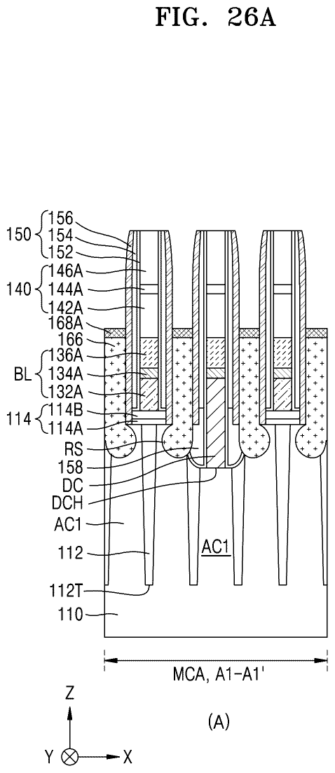

Referring to FIGS. 25A and 25B, a plurality of recessed spaces RS may be formed by removing a portion of structures exposed through the plurality of contact spaces 162S to expose the first active region AC1 of the substrate 110 between each of a plurality of bit lines BL.

To form the plurality of recessed spaces RS, an anisotropic etching process or a combination of an anisotropic etching process and an isotropic etching process may be used. For example, a portion of the third spacer layer 156 exposed through the plurality of contact spaces 162S between each of a plurality of bit lines BL and the substrate 110 located thereunder may be anisotropically etched, and a portion of the first active region AC1 of the substrate 110 exposed as a result of the etching may be isotropically etched to form the plurality of recessed spaces RS. Each of the plurality of recessed spaces RS may communicate with the contact space 162S. During the etching process for forming the contact space 162S, a portion of the spacer structure 150 and the buried insulating layer 158 may be consumed in a region adjacent to the upper surface of the substrate 110.

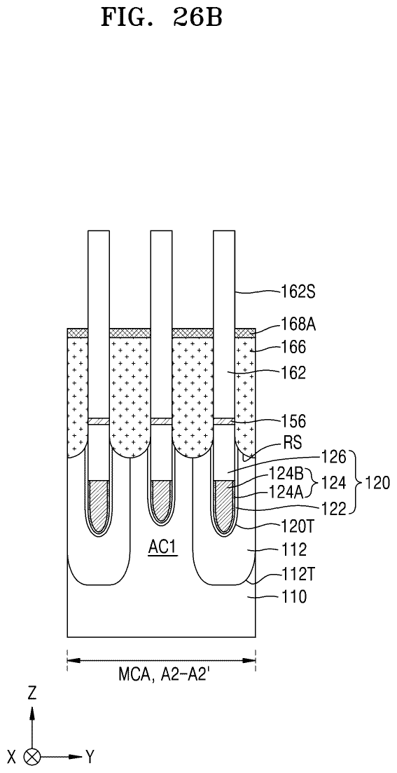

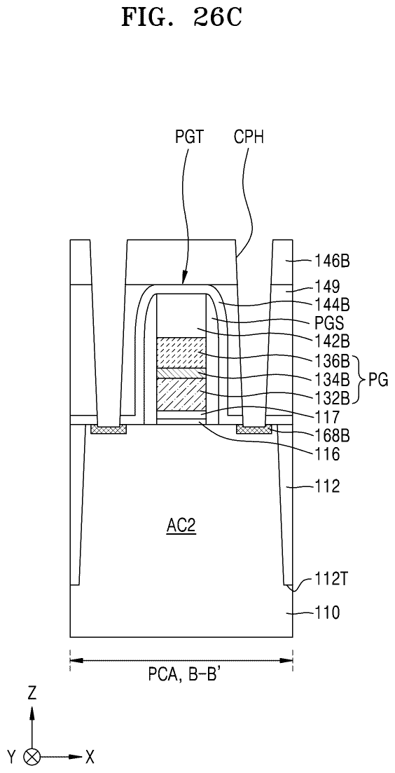

Referring to FIGS. 26A to 26C, a plurality of conductive plugs 166 are formed to fill a portion of the contact space 162S between each of the plurality of bit lines BL while filling the plurality of recessed spaces RS between each of the plurality of bit lines BL in the cell array region MCA.

Thereafter, in the peripheral circuit region PCA, the upper insulating capping layer 146B, the interlayer insulating film 149, and the passivation film 144B are etched, thereby forming a plurality of contact holes CPH that expose the second active region AC2 of the substrate 110.

Thereafter, in the cell array region MCA, a metal silicide film 168A may be formed on the conductive plugs 166 exposed through the plurality of contact spaces 162S, and in the peripheral circuit region PCA, a metal silicide film 168B may be formed on a surface of the second active region AC2 exposed through the plurality of contact holes CPH. The metal silicide films 168A and 168B may be formed simultaneously or in separate processes.

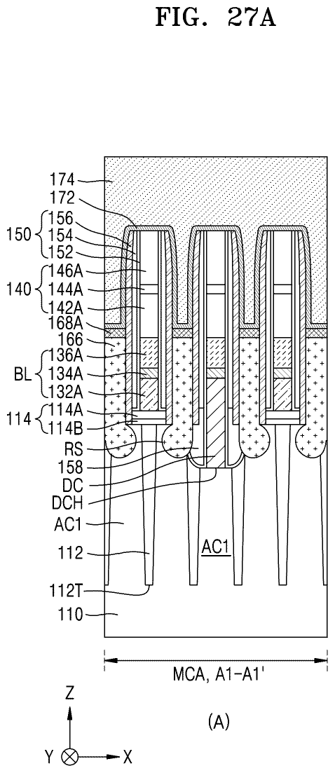

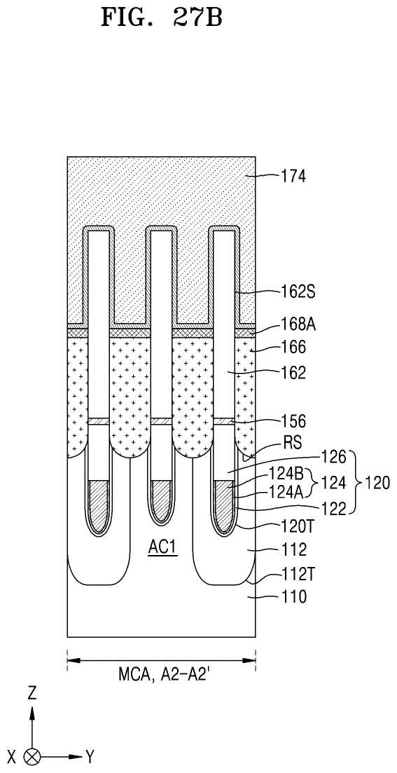

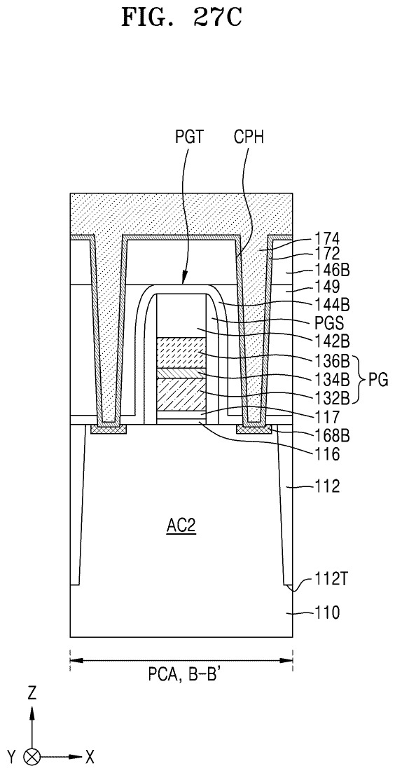

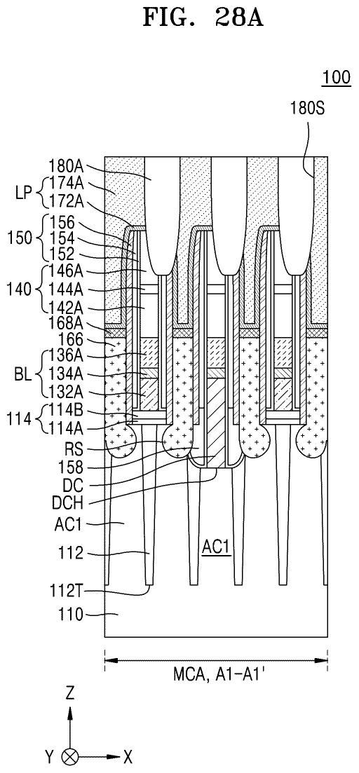

Referring to FIGS. 27A to 27C, in the cell array region MCA and the peripheral circuit region PCA, a conductive barrier film 172 and a conductive layer 174 covering the exposed surface on the substrate 110 may be formed.

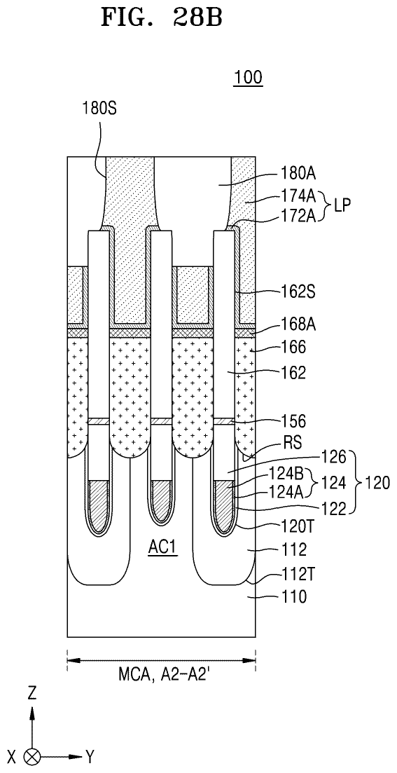

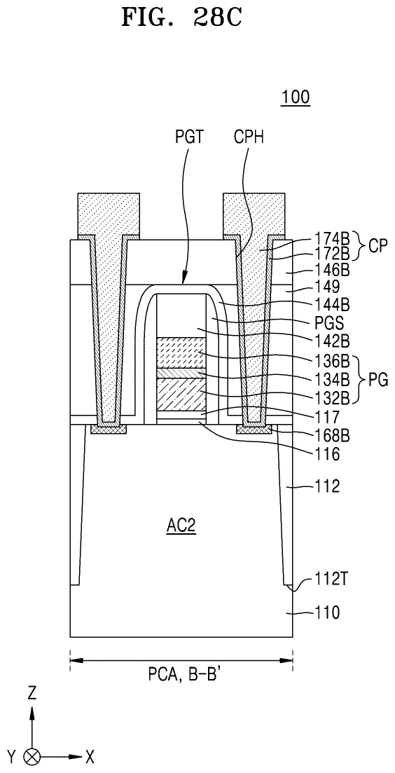

Referring to FIGS. 28A to 28C, in the cell array region MCA and the peripheral circuit region PCA, the conductive layer 174 and the conductive barrier film 172 are patterned to form a plurality of landing pads LP composed of a conductive barrier film 172A and a landing pad conductive layer 174A in the cell array region MCA, and a plurality of contact plugs CP composed of a conductive barrier film 172B and a landing pad conductive layer 174B are formed in the peripheral circuit region PCA. The plurality of landing pads LP may have a plurality of island-like pattern shapes in a plan view, as illustrated in FIG. 14A. The plurality of landing pads LP may be formed to vertically overlap with a portion of the plurality of bit lines BL on the metal silicide film 168A.

As the plurality of landing pads LP are formed in the island-like pattern shape, an insulating space 180S surrounding the plurality of landing pads LP may be formed, and at this time, the upper capping pattern 146A may be exposed on the inner wall of the insulating space 180S.

Thereafter, an insulating pattern 180 may be formed on the inner wall of the insulating space 180S in the cell array region MCA by using an insulating material. The insulating pattern 180 may be formed by spin coating, a chemical vapor deposition (CVD) process, a flowable CVD process, or the like.

Afterwards, a capacitor lower electrode (not shown) may be formed on the plurality of landing pads LP in the cell array region MCA.

The semiconductor device 100 is completed according to the manufacturing method described above.

The semiconductor device 100 includes a phase-separated crystallized region and an amorphous region by inducing crystallization only in a part of the dielectric film structure 117 through a heat treatment process, even when the dielectric film structure 117 has an extremely fine thickness within a range from about 18 Å to about 40 Å, and because the amorphous region blocks the flow of leakage current within a gate structure, the leakage current may be reduced or prevented.

As described above, embodiments have been disclosed in the drawings and the specification. In the present specification, the example embodiments are described by using some specific terms, but the terms used are for the purpose of describing the technical scope of the disclosed concepts only and are not intended to be limiting of meanings or the technical scope described in the claims. Therefore, it will be understood by those skilled in the art that various changes in form and details may be made therein without departing from the spirit and scope of the disclosed concepts as defined by the appended claims. Accordingly, the scope of the invention is defined not by the detailed description of the invention but by the appended claims.

What is claimed is:

1. A method of manufacturing a semiconductor device, the method comprising:
forming a gate interface film on a substrate;
forming, on the gate interface film, a preliminary dielectric film structure including a metal silicon oxide;
forming a dielectric film structure including a phase-separated first region and a second region by heat-treating the preliminary dielectric film structure at a temperature within a range of about 650 ° C. to about 850° C. in a nitrogen atmosphere;
forming a gate electrode on the preliminary dielectric film structure; and
forming a capping insulating film on the gate electrode,
wherein the heat-treating of the preliminary dielectric film structure includes:
heat-treating at a first temperature; and
heat-treating at a second temperature that is different from the first temperature.

2. The method of claim 1, wherein
the first region includes silicon at a first concentration, and
the second region includes silicon at a second concentration,
wherein the first concentration is less than the second concentration.

3. The method of claim 1, wherein the first region includes a crystallized region and the second region includes an amorphous region.

4. The method of claim 1, wherein the first region is spaced apart from the gate interface film or the gate electrode with the second region therebetween.

5. The method of claim 1, wherein
the second region includes a plurality of second regions, and
the first region is disposed between the plurality of second regions.

6. The method of claim 1, wherein
the first region includes a plurality of first regions, and
the second region is disposed between the plurality of first regions.

7. The method of claim 1, wherein
the first region includes a plurality of first regions, and
each of the plurality of first regions is surrounded by the second region.

8. The method of claim 1, wherein the nitrogen atmosphere includes an ammonia (NH₃) atmosphere.

9. The method of claim 1, wherein the second temperature is higher than the first temperature.

10. The method of claim 1, wherein the dielectric film structure has a thickness within a range from about 18 Å to about 30 Å in a direction perpendicular to an upper surface of the substrate.

11. The method of claim 1, wherein
the heat-treating at the first temperature is performed within a range of about 20 seconds to about 1 minute, and
the heat-treating at the second temperature is performed within a range of about 0.5 seconds to about 10 seconds.

12. A method of manufacturing a semiconductor device, the method comprising:
forming a gate interface film on a substrate;
forming a preliminary dielectric film structure including a metal silicon oxide on the gate interface film;
forming a dielectric film structure including a phase-separated first region and a second region by heat-treating the preliminary dielectric film structure in a nitrogen atmosphere;
forming a gate electrode on the dielectric film structure; and
forming a capping insulating film on the gate electrode,
wherein the heat-treating of the preliminary dielectric film structure includes:
heat-treating at a first temperature within a range of about 650° C. to about 750° C.; and
heat-treating at a second temperature within a range of about 750° C. to about 850° C.

13. The method of claim 12, wherein
the first region includes a crystallized region, and
the second region includes an amorphous region,
wherein the dielectric constant of the first region is higher than the dielectric constant of the second region.

14. The method of claim 12, wherein
the dielectric constant of the first region is within a range from about 18 to about 20, and
the dielectric constant of the second region is within a range from about 4 to about 5.

15. The method of claim 12, wherein the nitrogen atmosphere includes an ammonia (NH₃) atmosphere.

16. The method of claim 12, wherein the dielectric film structure includes nitrogen within an amount range of about 2 at % to about 20 at %.

17. The method of claim 12, wherein the metal silicon oxide includes at least one of hafnium (Hf), zirconium (Zr), lanthanum (La), and aluminum (Al).

18. A method of manufacturing a semiconductor device, the method comprising:
forming a gate interface film on a substrate;
forming a preliminary dielectric film structure including a metal silicon oxide on the gate interface film;
forming a dielectric film structure including a phase-separated first region and a second region by performing rapid thermal processing (RTP) on the preliminary dielectric film structure within a temperature range of about 650° C. to about 850° C.;
forming a gate electrode on the dielectric film structure; and
forming a capping insulating film on the gate electrode,
wherein the first region includes a crystallized region and has a dielectric constant within a range from about 18 to about 20, and
the second region includes an amorphous region and has a dielectric constant within a range from about 4 to about 5.

19. The method of claim 18, wherein
the rapid heat treatment includes:
heat treatment at a first temperature within a range of about 650° C. to about 750° C.; and
heat treatment at a second temperature within a range of about 750 to about 850° C.,
wherein the heat treatment is performed by rapid thermal processing (RTP) in an ammonia atmosphere.

20. The method of claim 18, wherein
the heat-treating at the first temperature is performed within a range of about 20 seconds to about 1 minute, and
the heat-treating at the second temperature is performed within a range of about 0.5 seconds to about 10 seconds.
